(19) United States
(12) Patent Application Publication
(10) Pub. No.: US 2025/0309214 A1
(43) Pub. Date: Oct. 2, 2025

(54) MODULE

(71) Applicant: CANON KABUSHIKI KAISHA, Tokyo (JP)

(72) Inventors: HIROYUKI YAMAGUCHI, Kanagawa (JP); MOMOKA UMEGAE, Kanagawa (JP); YOSHITOMO FUJISAWA, Kanagawa (JP)

(21) Appl. No.: 19/085,710

(22) Filed: Mar. 20, 2025

(30) Foreign Application Priority Data
Mar. 26, 2024 (JP) 2024-050038
Oct. 21, 2024 (JP) 2024-185243

(51) Int. Cl. H01L 25/18; H01L 23/538; H10D 1/40; H10D 1/60

(52) U.S. Cl. CPC H01L 25/18; H01L 23/5384; H10D 1/40; H10D 1/60

(57) ABSTRACT

A module according to this disclosure comprising: a wiring board; a first chip component that has a first electrode portion, a first non-electrode portion, and a second electrode portion and is provided on the wiring board; and a second chip component that has a third electrode portion, a second non-electrode portion, and a fourth electrode portion and is stacked on the first chip component; wherein the second electrode portion is electrically isolated from the third electrode portion and the fourth electrode portion, wherein the second electrode portion is located between the second non-electrode portion and the wiring board.

### BACKGROUND

### Field of the Technology

This disclosure relates to a module.

### Description of the Related Art

In recent years, the miniaturization and densification of electronic circuits have progressed remarkably due to the integration of integrated circuits (ICs). However, individual circuit components such as capacitors and resistors are still used for peripheral circuits of ICs. The components are mounted on a printed circuit board to form a printed circuit board. To realize high functionality of electronic devices, the number of signals handled by ICs and the operating speed are increasing. Therefore, the number of components required for signal waveform shaping, and noise control of signals and power supplies tends to increase.

Components mounted on the printed circuit boards are increasingly becoming chips, and chip components such as chip capacitors and chip resistors are being miniaturized. However, due to the increasing of component mounting and the demand for miniaturization of electronic devices, there is an increasing need to increase the mounting density of chip components on printed circuit boards.

In response to the situation, there are attempts to increase the volume utilization of electronic devices, including printed circuit boards and to dispose electronic components in a three-dimensional manner, thereby achieving electronic devices such as small, printed circuit boards or small control devices. For example, Japanese Patent Application Laid-Open No. 2005-216884 discloses a configuration in which a plurality of chip components is mounted on the circuit board, and another chip component is stacked thereon.

### SUMMARY

A module according to this disclosure comprising: a wiring board; a first chip component that has a first electrode portion, a first non-electrode portion, and a second electrode portion and is provided on the wiring board; and a second chip component that has a third electrode portion, a second non-electrode portion, and a fourth electrode portion and is stacked on the first chip component; wherein the second electrode portion is electrically isolated from the third electrode portion and the fourth electrode portion, wherein the second electrode portion is located between the second non-electrode portion and the wiring board.

Further features of the present disclosure will become apparent from the following description of exemplary embodiments with reference to the attached drawings.

### BRIEF DESCRIPTION OF THE DRAWINGS

FIG. 1 is a schematic diagram illustrating an electronic device according to a first embodiment.

FIG. 2A is a plane view illustrating a processing module according to the first embodiment.

FIG. 2B is a cross-sectional view along a dotted line A101-A′101 in FIG. 2A.

FIG. 3A is a plane view illustrating a processing module of a comparative example.

FIG. 3B is a cross-sectional view along a dotted line A51-A′51 in FIG. 3A.

FIG. 4A is a plane view illustrating a processing module according to a second embodiment.

FIG. 4B is a cross-sectional view along a dotted line A201-A′201 in FIG. 4A.

FIG. 5A is a plane view illustrating a processing module according to a third embodiment.

FIG. 5B is a cross-sectional view of the XZ plane along a dotted line A301-A′301 in FIG. 5A.

FIG. 5C is a cross-sectional view of the XY plane along a dotted line B301-B′301 in FIG. 5B.

FIG. 6A is a plane view illustrating a processing module according to a comparative example to explain the effect of the third embodiment.

FIG. 6B is a cross-sectional view of the XZ plane along a dotted line A351-A′351 in FIG. 6A.

FIG. 6C is a cross-sectional view of the XY plane along a dotted line B351-B′351 in FIG. 6B.

FIG. 7 is a diagram illustrating simulation results of the power supply impedance of an example 1 and the comparative example.

FIG. 8A is a plane view illustrating a processing module according to a fourth embodiment.

FIG. 8B is a cross-sectional view of the XY plane along a dotted line A401-A′401 in FIG. 8A.

FIG. 8C is a cross-sectional view of the XY plane along a dotted line B401-B′401 in FIG. 8B.

FIG. 9A is a plane view illustrating a processing module according to a comparative example to explain the effect of the fourth embodiment.

FIG. 9B is a cross-sectional view of the XZ plane along a dotted line A451-A′451 in FIG. 9A.

FIG. 9C is a cross-sectional view of the XY plane along a dotted line B451-B′451 in FIG. 9B.

FIG. 10 is a diagram illustrating the simulation results of the power supply impedance of the second example and the comparative example.

FIG. 11A is a plane view illustrating a processing module according to a fifth embodiment.

FIG. 11B is a cross-sectional view illustrating the processing module according to the fifth embodiment.

FIG. 11C is a cross-sectional view of the XY plane along a dotted line B501-B′501 in FIG. 11B.

FIG. 11D is a diagram illustrating the processing module according to the fifth embodiment represented by an equivalent circuit.

FIG. 12A is a plane view illustrating the processing module according to a comparative example for explaining the effect of the fifth embodiment.

FIG. 12B is a cross-sectional view illustrating a processing module according to a comparative example of the fifth embodiment.

FIG. 12C is a cross-sectional view of the XY plane at a dotted line B556-B′556 in FIG. 12B.

FIG. 12D is a diagram illustrating the processing module according to the comparative example represented by an equivalent circuit.

FIG. 13 is a diagram illustrating the simulation results of the power supply impedance of the third example and the comparative example.

FIG. 14A is a plane view illustrating a processing module according to a sixth embodiment.

FIG. 14B is a side view illustrating a processing module according to the sixth embodiment.

FIG. 14C is a cross-sectional view of the XY plane along a dotted line B601-B′601 in FIG. 14B.

FIG. 15A is a plane view illustrating a processing module according to a seventh embodiment.

FIG. 15B is a side view illustrating the processing module according to the seventh embodiment.

FIG. 15C is a cross-sectional view of the XY plane along dotted line B701-B′701 in FIG. 15B.

FIG. 15D is a cross-sectional view of the XY plane along dotted line C701-C′701 in FIG. 15B.

FIG. 16A is a plane view illustrating a processing module according to an eighth embodiment.

FIG. 16B is a side view illustrating the processing module according to the eighth embodiment.

FIG. 16C is a cross-sectional view of the XY plane along a dotted line B801-B′801 in FIG. 16B.

FIG. 16D is a cross-sectional view of the XY plane along a dotted line C801-C′801 in FIG. 16B.

FIG. 17A is a plane view illustrating the processing module according to a ninth embodiment.

FIG. 17B is a side view illustrating the processing module according to the ninth embodiment.

FIG. 17C is a cross-sectional view of the XY plane along a dotted line B901-B′901 in FIG. 17B.

FIG. 17D is a cross-sectional view of the XY plane along a dotted line C901-C′901 in FIG. 17B.

FIG. 18A is a plane view illustrating the processing module according to a tenth embodiment.

FIG. 18B is a side view illustrating the processing module according to the tenth embodiment.

FIG. 18C is a cross-sectional view of the XY plane along a dotted line B1001-B′1001 in FIG. 18B.

FIG. 18D is a cross-sectional view of the XY plane along a dotted line C1001-C′1001 in FIG. 18B.

FIG. 19A is a plane view illustrating the processing module according to an eleventh embodiment.

FIG. 19B is a side view illustrating the processing module according to the eleventh embodiment.

FIG. 19C is a cross-sectional view of the XY plane along a dotted line B1101-B′1101 in FIG. 19B.

FIG. 19D is a cross-sectional view of the XY plane along a dotted line C1101-C′1101 in FIG. 19B.

FIG. 20A is a side view illustrating a processing module according to a twelfth embodiment.

FIG. 20B is a plane view illustrating a processing module according to the twelfth embodiment.

FIG. 20C is a cross-sectional view of the XY plane along a dotted line B1201-B′1201 in FIG. 20A.

FIG. 21A is a perspective view for explaining a manufacturing process of a processing module according to a thirteenth embodiment.

FIG. 21B is a perspective view for explaining a manufacturing process of the processing module according to the thirteenth embodiment.

FIG. 21C is a side view illustrating the processing module according to the thirteenth embodiment.

FIG. 21D is a plane view illustrating the processing module according to the thirteenth embodiment.

FIG. 21E is a cross-sectional view of the XY plane along a dotted line B1301-B′1301 in FIG. 21C.

FIG. 22A is a plane view illustrating a processing module according to a fourteenth embodiment.

FIG. 22B is a cross-sectional view of the XY plane of the processing module according to the fourteenth embodiment.

FIG. 23A is a plane view illustrating the processing module according to a fifteenth embodiment.

FIG. 23B is a cross-sectional view of the XY plane of the processing module according to the fifteenth embodiment.

FIG. 24A is a plane view illustrating a processing module according to a sixteenth embodiment.

FIG. 24B is a cross-sectional view illustrating the processing module according to the sixteenth embodiment.

FIG. 24C is a cross-sectional view of the XY plane along a dotted line B1601-B′1601 in FIG. 24B.

FIG. 24D is a diagram illustrating the processing module according to the sixteenth embodiment represented by an equivalent circuit.

FIG. 25A is a plane view illustrating a processing module according to a seventeenth embodiment.

FIG. 25B is a cross-sectional view of the XZ plane along a dotted line A1701-A′1701 in FIG. 25A.

FIG. 25C is a side view along the X-direction of the processing module according to the seventeenth embodiment.

FIG. 26A is a side view illustrating a processing module according to an eighteenth embodiment.

FIG. 26B is a side view illustrating the processing module according to the eighteenth embodiment.

FIG. 26C is a cross-sectional view of the XY plane along a dotted line B1801-B′1801 in FIG. 26A.

FIG. 26D is a cross-sectional view of the XY plane along a dotted line C1801-C′1801 in FIG. 26A.

FIG. 27A is a plane view illustrating a processing module according to a nineteenth embodiment.

FIG. 27B is a cross-sectional view along a dotted line B-B′ in FIG. 27A.

FIG. 28A is a plane view illustrating the processing module according to a twentieth embodiment.

FIG. 28B is a cross-sectional view along a dotted line C-C′ in FIG. 28A.

FIG. 28C is a cross-sectional view along the dotted line C-C′ in FIG. 28A.

### DESCRIPTION OF THE EMBODIMENTS

Hereinafter, an embodiment of the present disclosure will be described in detail with reference to the drawings. It should be noted that the present disclosure is not limited to the following embodiments and may be modified as needed within the scope of the present disclosure. In the drawings to be described below, components having the same function may be given the same reference numerals and their description may be omitted or simplified.

### First Embodiment

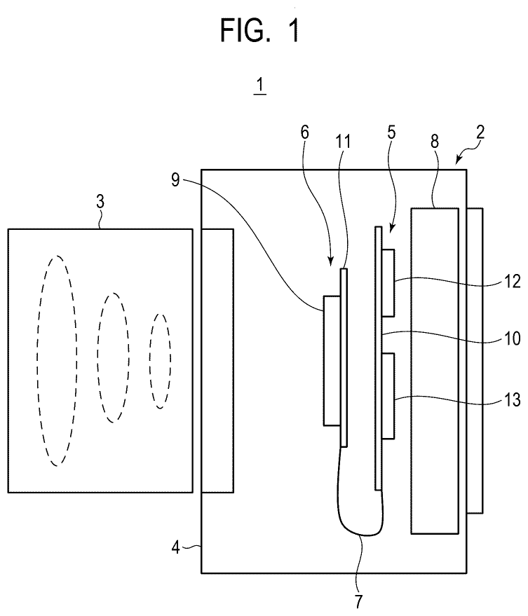

FIG. 1 is a schematic diagram illustrating an example of an electronic device according to a first embodiment. Here, a digital camera 1 which is an imaging apparatus is illustrated as an electronic device. The digital camera 1 is a lens-interchangeable digital camera and includes a camera body 2. A lens unit (lens barrel) 3, including a lens, is detachably provided in the camera body 2. The camera body 2 includes a housing 4, a processing module 5, and a sensor module 6. The processing module 5 and the sensor module 6 are disposed of inside the housing 4.

The processing module 5 is an example of an electronic module and is composed of a printed circuit board. The processing module 5 and the sensor module 6 are electrically connected by a connecting member 7. The connecting member 7 may include a flexible printed circuit board (FPC), a flexible flat cable (FFC), a connector, and the like. A battery 8 is disposed inside the housing 4. The battery 8 is a power source for supplying power to the processing module 5, the sensor module 6, and the like. The sensor module 6 has an image sensor 9 which is an imaging device, and a printed circuit board 11. The printed circuit board 11 is a rigid circuit board. The image sensor 9 is mounted on the printed circuit board 11.

The image sensor 9 is, for example, a complementary metal oxide semiconductor (CMOS) image sensor or a charge coupled device (CCD) image sensor. The image sensor 9 has a function of converting light incident via the lens unit 3 into an electric signal. The processing module 5 has a power supply unit 12, a load unit 13, and a printed wiring board 10. The printed wiring board 10 is a rigid wiring board. The power supply unit 12 and the load unit 13 are mounted on the printed wiring board 10.

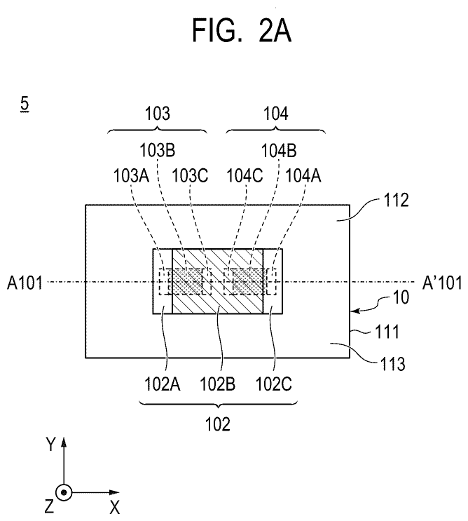

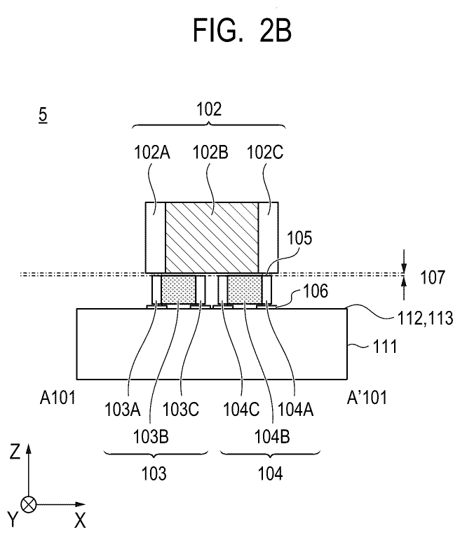

FIG. 2A is a plane view illustrating the processing module 5 according to the first embodiment. FIG. 2B is a cross-sectional view of the processing module 5 along a dotted line A101-A′101 in FIG. 2A. The printed wiring board 10 has an insulating substrate 111 and at least one conductor layer. The at least one conductor layer includes a surface layer 113 located on a main surface 112 of the insulating substrate 111. The power supply unit 12 and the load unit 13 are disposed on the main surface 112 of the insulating substrate 111. That is, the power supply unit 12 and the load unit 13 are disposed on the surface layer 113. The insulating substrate 111 is formed of an electrically insulating insulator, such as glass epoxy resin. On the surface layer 113, conductor patterns for forming various kinds of wiring such as power supply wiring, ground wiring, and signal wiring are disposed. The conductor patterns are formed of metal, such as copper or gold.

The load unit 13 includes a plurality of loads, such as semiconductor devices. The load may be, for example, a digital signal processor. The digital processor has a function of acquiring electrical signals from the image sensor 9, correcting the acquired electrical signals, and generating image data. The load may be, for example, a memory device such as a dynamic random-access memory (DRAM). The memory device has a function of transmitting and receiving electrical signals with the aforementioned digital signal processor and temporarily storing data such as image data. The processing module 5 has a power supply wiring unit (not illustrated). The power supply wiring unit is used to supply the voltage output from the power supply unit 12 to a plurality of loads of the load unit 13.

The first chip component 103 and the third chip component 104 are disposed on the surface layer 113 of the printed wiring board 10. The second chip component 102 is stacked on the first chip component 103 and the third chip component 104. The first chip component 103, the second chip component 102, and the third chip component 104 are chip components such as capacitors, resistors, inductors, and the like.

The first chip component 103 has a first electrode portion 103A, a first non-electrode portion 103B, and a second electrode portion 103C. The second chip component 102 has a third electrode portion 102A, a second non-electrode portion 102B, and a fourth electrode portion 102C. The third chip component 104 has a fifth electrode portion 104A, a third non-electrode portion 104B, and a sixth electrode portion 104C. The first electrode portion 103A and the third electrode portion 102A are electrically connected using a conductive adhesive 105 such as solder. In each chip component, a non-electrode portion is provided between a pair of electrode portions.

Similarly, the fifth electrode portion 104A of the third chip component 104 and the fourth electrode portion 102C of the second chip component 102 are electrically connected by the conductive adhesive 105. That is, the conductive adhesive 105 forms a conductive adhesive layer. The first electrode portion 103A and the second electrode portion 103C of the first chip component 103, and the fifth electrode portion 104A and the sixth electrode portion 104C of the third chip component 104 are connected to the printed wiring board 10 via a conductive pad 106. The conductive adhesive 105 may be used instead of the conductive pad 106. The conductive pad 106 is connected to the load unit 13 via a wiring (not illustrated) formed on the printed wiring board 10.

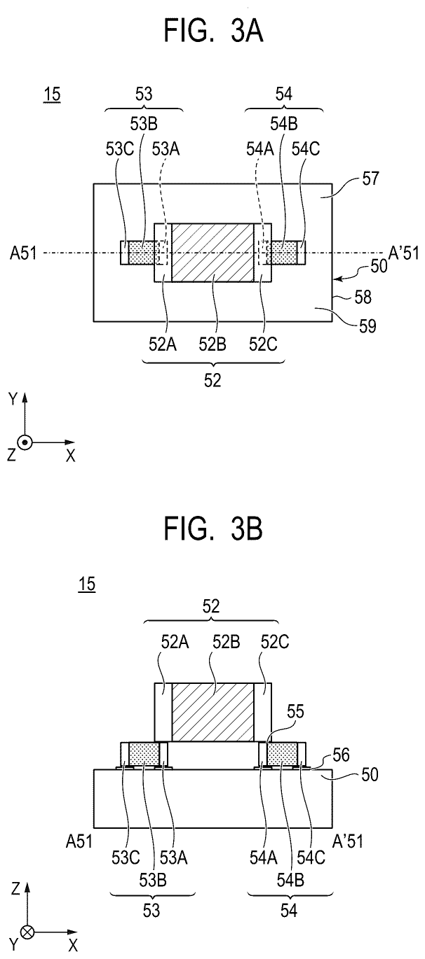

FIG. 3A is a plane view illustrating a processing module 15 of a comparative example. FIG. 3B is a cross-sectional view along a dotted line A51-A′51 in FIG. 3A. The first chip component 53 and the third chip component 54 are disposed on the surface layer 59 of the printed wiring board 50. The second chip component 52 is stacked on the first chip component 53 and the third chip component 54. The first chip component 53, the second chip component 52, and the third chip component 54 are chip components such as capacitors, resistors, inductors, and the like.

The first chip component 53 has a first electrode portion 53A, a first non-electrode portion 53B, and a second electrode portion 53C. The second chip component 52 has a third electrode portion 52A, a second non-electrode portion 52B, and a fourth electrode portion 52C. The third chip component 54 has a fifth electrode portion 54A, a third non-electrode portion 54B, and a sixth electrode portion 54C. In each chip component, the non-electrode portion is provided between a pair of electrode portions.

The first electrode portion 53A of the first chip component 53 and the third electrode portion 52A of the second chip component 52 are connected using a conductive adhesive 55 such as solder. Similarly, the fifth electrode portion 54A of the third chip component 54 and the fourth electrode portion 52C of the second chip component 52 are connected using a conductive adhesive 55. The first electrode portion 53A, the second electrode portion 53C, the fifth electrode portion 54A, and the sixth electrode portion 54C are connected to the printed wiring board 50 via a conductive pad 56. The conductive adhesive 55 may be used instead of the conductive pad 56. The conductive pad 56 is also connected to a load unit (not illustrated) via a wiring (not illustrated) formed on the printed wiring board 50.

In the plane view along the Z-direction, the second electrode portion 53C of the first chip component 53 and the sixth electrode portion 54C of the third chip component 54 are located outside the second chip component 52. The second electrode portion 53C of the first chip component 53 is not electrically connected to the third electrode portion 52A and the fourth electrode portion 52C of the second chip component 52. In other words, the second electrode portion 53C of the first chip component 53 is electrically isolated from the third electrode portion 52A and the fourth electrode portion 52C of the second chip component 52. Similarly, the fifth electrode portion 54A of the third chip component 54 is electrically isolated from the third electrode portion 52A and the fourth electrode portion 52C of the second chip component 52.

As illustrated in FIG. 3A and FIG. 3B, when a chip component in the upper stage and a chip component in the lower stage are stacked so that the electrodes of the chip component in the upper stage and the electrodes of the chip component in the lower stage are directly connected, the width of the gap between the plurality of chip components in the lower stage is limited by the distance between the electrodes of the chip components in the upper stage. That is, the distance between the chip components in the lower stage cannot be made closer than the distance between the electrodes determined by the size of the chip components in the upper stage. As a result, the gap between the chip components in the lower stage becomes a dead space, and the flexibility of mounting layout of the chip components is limited.

In the first embodiment and the comparative example, the sizes of the second chip components 102, 52 are larger than the sizes of the first chip components 103, 53 and the third chip components 104, 54. For example, the first chip components 103, 53 and the third chip components 104, 54 are chip components having a size of 0.4 mm×0.2 mm (Hereinafter referred to as “0402 size”). The second chip components 102, 52 are chip components having a size of 1.0 mm×0.5 mm (Hereinafter referred to as “1005 size”).

As illustrated in FIG. 2A and FIG. 3A, which are plane views, when the occupied area of chip component on the printed wiring board 10 is compared with the occupied area of chip component on the printed wiring board 50, the occupied area in the first embodiment is smaller than the occupied area in the comparative example. Thereby, the chip components can be disposed at a higher density. When the occupied areas are compared in the example of the component size described above, the occupied area is 0.632 mm² in the comparative example and is 0.5 mm² in the first embodiment. Thereby, reducing the occupied area is achieved. When expressed in terms of the number of components that can be disposed per unit area, the number of components is six pieces/mm² in the first embodiment while 4.7 pieces/mm² in the comparative example. As described above, according to the first embodiment of the present disclosure, it is possible to mount components at a higher density than in the comparative example, and the flexibility in the layout of components and wiring is improved.

In the first embodiment, there is a minute gap 107 between the first chip component 103 and the second chip component 102 and between the third chip component 104 and the second chip component 102 due to the thickness of the adhesive layer formed by the conductive adhesive 105. The distance of the gap 107 in the stacking direction (Z-direction) between the first chip component 103 and the second chip component 102 is, for example, less than 200 μm. In the gap 107, the second electrode portion 103C of the first chip component 103 is electrically isolated from the third electrode portion 102A and the fourth electrode portion 102C of the second chip component 102. Similarly, the sixth electrode portion 104C of the third chip component 104 is electrically isolated from the third electrode portion 102A and the fourth electrode portion 102C of the second chip component 102.

The second electrode portion 103C of the first chip component 103 is positioned between the second non-electrode portion 102B of the second chip component 102 and the printed wiring board 10. The second electrode portion 103C of the first chip component 103 overlaps with the second non-electrode portion 102B of the second chip component 102 in the plane view along the Z-direction. The sixth electrode portion 104C of the third chip component 104 is positioned between the second non-electrode portion 102B and the printed wiring board 10. The sixth electrode portion 104C of the third chip component 104 overlaps with the second non-electrode portion 102B of the second chip component 102 in the plane view along the Z-direction.

As described above, the second electrode portion 103C of the first chip component 103 and the sixth electrode portion 104C of the third chip component 104 are electrically isolated from the third electrode portion 102A and the fourth electrode portion 102C of the second chip component 102 in the gap 107. By disposing the second electrode portion 103C of the first chip component 103 and the sixth electrode portion 104C of the third chip component 104 so as to overlap with the second non-electrode portion 102B in the plane view along the Z-direction, a plurality of chip components can be disposed with high density.

The case of interposing an interposer substrate or the like is provided between the first chip component 103 and the second chip component 102 and between the third chip component 104 and the second chip component 102, respectively, is described. In this case, parasitic resistance and inductance of the wiring are generated between the electrically connected electrodes (Between the first electrode portion 103A of the first chip component 103 and the third electrode portion 102A of the second chip component 102, between the fifth electrode portion 104A of the third chip component 104 and the fourth electrode portion 102C of the second chip component 102, etc.). Thereby, the impedance in the path between the load unit and the chip component increases.

On the other hand, in the first embodiment, there is no interposer substrate or the like between the first chip component 103 and the second chip component 102 and between the third chip component 104 and the second chip component 102, respectively. Thereby, the impedance in the path between the load unit and the chip component can be kept low. In the first embodiment, the power supply unit 12, the load unit 13, the first chip component 103, the second chip component 102, and the third chip component 104 are disposed on the same surface of the surface layer 113 of the printed wiring board 10. However, these components do not have to be disposed on the same surface.

### Second Embodiment

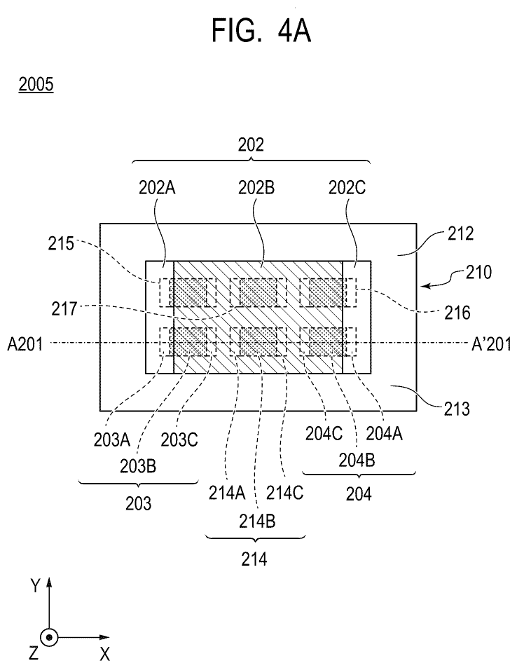

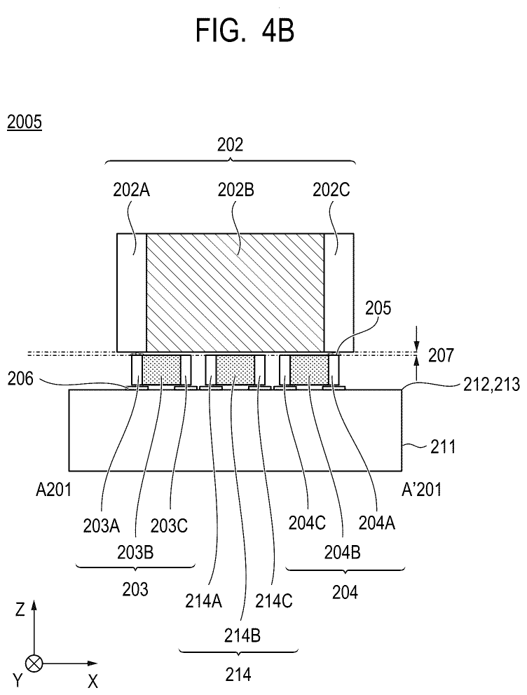

FIG. 4A is a plane view illustrating a processing module 2005 according to a second embodiment. FIG. 4B is a cross-sectional view along a dotted line A201-A′201 in FIG. 4A. The differences between the second embodiment and the first embodiment will be described below. In the second embodiment, in addition to the first chip component 203 and the third chip component 204, a fourth chip component 214, a fifth chip component 215, a sixth chip component 216, and a seventh chip component 217 are disposed between the second non-electrode portion 202B of the second chip component 202 and the printed wiring board 210.

In the second embodiment, the size of the second chip component 202 is larger than the sizes of the first chip component 203, the third chip component 204, and the fourth chip component 214. For example, the first chip component 203, the third chip component 204, and the fourth chip component 214 are chip components of 0402 size, and the second chip component is chip components of 1608 size. When the number of components that can be disposed per unit area is calculated, the number of components is 4.7/mm² in the comparative example and is 5.4/mm² in the second embodiment. That is, since many components can be disposed in a narrow area, the flexibility of layout of components and wiring can be improved. The size of each chip component is not limited to that described above. The length of the long side of the second chip component 202 should be longer than the length of the long side of the first chip component 203, the third chip component 204, and the fourth chip component 214. For example, the length of long side of the first chip component 203, the third chip component 204, and the fourth chip component 214 are less than half of the length of the long side of the second chip component 202.

The seventh electrode portion 214A and the eighth electrode portion 214C of the fourth chip component 214 are electrically isolated from the third electrode portion 202A and the fourth electrode portion 202C of the second chip component 202 in the gap 207. The first chip component 203, the third chip component 204, and the fourth chip component 214 are disposed linearly along the longitudinal direction of the second chip component 202. In the plane view along the Z-direction, the seventh electrode portion 214A and the eighth electrode portion 214C of the fourth chip component 214 overlap with the second non-electrode portion 202B of the second chip component 202.

As described above, the seventh electrode portion 214A and the eighth electrode portion 214C of the fourth chip component 214 are electrically isolated from the third electrode portion 202A and the fourth electrode portion 202C of the second chip component 202 via a gap 207. Then, by disposing the seventh electrode portion 214A and the eighth electrode portion 214C of the fourth chip component 214 so as to overlap the second non-electrode portion 202B of the second chip component 202 in the plane view along the Z-direction, the components can be disposed with high density. Furthermore, as illustrated in FIG. 4A, the fifth chip component 215, the sixth chip component 216, and the seventh chip component 217 are additionally disposed in the positive Y-direction of the fourth chip component 214. Thereby, the chip components can be disposed with high density on the printed wiring board 210.

The fourth chip component 214 do not have to be electrically connected to the first chip component 203, the second chip component 202, and the third chip component 204. The components may be connected so that a pair of electrodes of the first chip component 203, a pair of electrodes of the second chip component 202, and a pair of electrodes of the third chip component 204 have a power supply potential V201 and a GND potential G201. The components may be connected so that the pair of electrodes of the fourth chip component 214 have a power supply potential V202 and a GND potential G202. Whether or not the components should be electrically connected or not can be selected according to the desired circuit.

### Third Embodiment

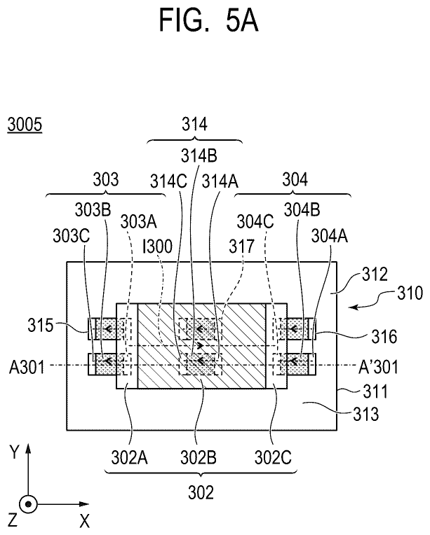

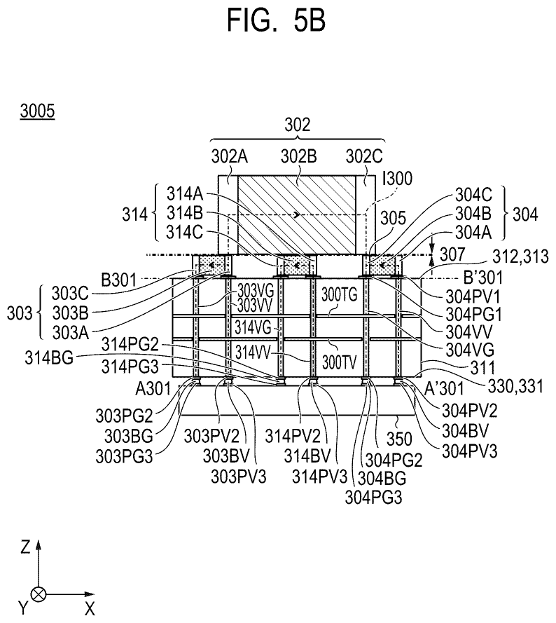

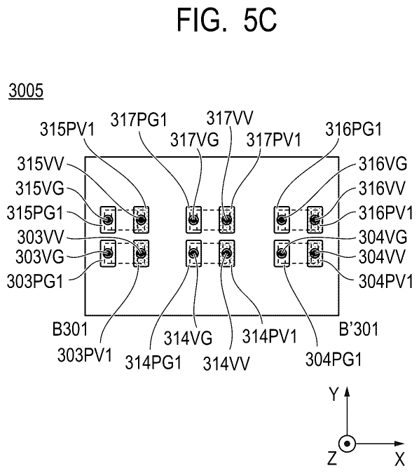

FIG. 5A is a plane view illustrating a processing module 3005 according to a third embodiment. FIG. 5B is a cross-sectional view of the XZ plane along a dotted line A301-A′301 in FIG. 5A. FIG. 5C is a cross-sectional view of the XY plane along a dotted line B301-B′301 in FIG. 5B. The differences between the third embodiment and the second embodiment will be described below.

In the third embodiment, a semiconductor device 350 is mounted on the surface layer 331 located on a surface 330 opposite to a main surface 312 of an insulating substrate 311. The semiconductor device 350 is an example of a load, for example, a DRAM. A first chip component 303, a second chip component 302, a third chip component 304, a fourth chip component 314, a fifth chip component 315, a sixth chip component 316, and a seventh chip component 317 are capacitors in the third embodiment. In the third embodiment, the second chip component 302 has a larger component size than the first chip component 303, the third chip component 304, the fourth chip component 314, the fifth chip component 315, the sixth chip component 316, and the seventh chip component 317. For example, the second chip component 302 may be a chip component of 1608 size, and the other chip components may be chip components of 0402 size.

A first electrode portion 303A of the first chip component 303 is connected to the power terminal of the semiconductor device 350 via the conductive adhesive 305, the power supply pad 303PV1, the power supply via 303VV, the power supply pad 303PV2, the connecting unit 303BV, and the power supply pad 303PV3.

The second electrode portion 303C of the first chip component 303 is connected to a GND terminal of the semiconductor device 350 via the conductive adhesive 305, a GND pad 303PG1, a GND via 303VG, a GND pad 303PG2, the connecting unit 303BG, and a GND pad 303PG3.

The sixth electrode portion 304C of the third chip component 304 is connected to the power terminal of the semiconductor device 350 via the conductive adhesive 305, a power supply pad 304PV1, a power supply via 304VV, a power supply pad 304PV2, a connecting unit 304BV, and a power supply pad 304PV3.

The fifth electrode portion 304A of the third chip component 304 is connected to a GND terminal of the semiconductor device 350 via the conductive adhesive 305, a GND pad 304PG1, a GND via 304VG, a GND pad 304PG2, a connecting unit 304BG, and a GND pad 304PG3.

The eighth electrode portion 314C of the fourth chip component 314 is connected to a power terminal of the semiconductor device 350 via the conductive adhesive 305, a power supply pad 314PV1, a power supply via 314VV, a power supply pad 314PV2, a connecting unit 314BV, and a power supply pad 314PV3.

The seventh electrode portion 314A of the fourth chip component 314 is connected to the GND terminal of the semiconductor device 350 via the conductive adhesive 305, a GND pad 314PG1, a GND via 314VG, a GND pad 314PG2, a connecting unit 314BG, and a GND pad 314PG3.

The third electrode portion 302A of the second chip component 302 is connected to the power terminal of the semiconductor device 350 via the conductive adhesive 305 and the first electrode portion 303A of the first chip component 303. The fourth electrode portion 302C of the second chip component 302 is connected to the GND terminal of the semiconductor device 350 via the conductive adhesive 305 and the second electrode portion 303C of the first chip component 303.

Similarly, the electrodes of the fifth chip component 315, the sixth chip component 316, and the seventh chip component 317 are connected to the semiconductor device 350 via the conductive pads, vias, and the like. As illustrated in FIG. 5B, the plurality of power supply vias and the plurality of GND vias are disposed in parallel with each other in cross-sectional view.

The first electrode portion 303A, the fifth electrode portion 304A, the seventh electrode portion 314A, the ninth electrode portion 315A, the eleventh electrode portion 316A, and the thirteenth electrode portion 317A are electrically connected via the power supply pads, the power supply vias, and the power supply wiring 300TV. The second electrode portion 303C, the sixth electrode portion 304C, the eighth electrode portion 314C, the tenth electrode portion 315C, the twelfth electrode portion 316C, and the fourteenth electrode portion 317C are electrically connected via GND pads, GND vias, and GND wiring 300TG. A gap 307 partially exists between the fourth chip component 314 and the second chip component 302. Therefore, the seventh electrode portion 314A and the eighth electrode portion 314C of the fourth chip component 314 are electrically isolated from the third electrode portion 302A and the fourth electrode portion 302C of the second chip component 302 via the gap 307.

The third embodiment differs from the second embodiment in that the chip components are disposed so that parts of the first chip component 303, the third chip component 304, the fifth chip component 315, and the sixth chip component 316 are outside the second chip component. As described above, using the inter-terminal pitch and the inter-via pitch of the semiconductor device 350, a plurality of chip components (303, 304, 314, 315, 316, 317) disposed in the lower stage of the stacked chip components can be adjusted to an optimum placement. Further, by disposing the chip components disposed in the lower stage at a wide interval, the risk of short circuit in soldering the components can be reduced.

In FIG. 5A and FIG. 5B, the direction of the current in the processing module 3005 is indicated by a dotted line 1300. Here, the direction of the current in the second chip component 302 is opposed to the direction of the current in the fourth chip component 314 and the seventh chip component 317. Since opposing currents work to cancel each other's magnetic fields, parasitic inductance (=ESL) of capacitors can be reduced between the second chip component 302 and the fourth chip component 314, and between the second chip component 302 and the seventh chip component 317.

Further, in the plane view, a plurality of vias is disposed at positions so that a plurality of vias overlap with the respective electrode portions of the first chip component 303, the third chip component 304, and the fourth chip component 314. For example, in the plane view, the plurality of vias is disposed so that the first electrode portion 303A of the first chip component 303 overlaps the power supply via 303VV, and the second electrode portion 303B overlaps the GND via 303VG.

In addition, electric currents face each other between the power supply via 304VV and the GND via 304VG, between the power supply via 314VV and the GND via 314VG, between the power supply via 303VV and the GND via 303VG, between the power supply via 315VV and the GND via 315VG, between the power supply via 316VV and the GND via 316VG, and between the power supply via 317VV and the GND via 317VG. Specifically, in FIG. 5B, the direction of the current in the power supply via 304VV is in the positive Z-direction. The GND via 304VG is adjacent to the power supply via 304VV in the negative X-direction. In FIG. 5B, the direction of the current in the GND via 304VG is in the negative Z-direction.

In addition, electric currents face each other between the power supply via 314VV and the GND via 304VG, between the power supply via 317VV and the GND via 316VG, between the power supply via 315VV and the GND via 317VG, and between the power supply via 317VV and the GND via 316VG. Specifically, in FIG. 5B, the direction of the current in the power supply via 314VV is in the positive Z-direction. The GND via 304VG is adjacent to the power supply via 314VV in the positive X-direction. In FIG. 5B, the direction of the current in the GND via 304VG is in the negative Z-direction. Since opposing currents work to cancel each other's magnetic fields, the inductance of the power supply via and the GND via can be reduced.

When the inductance is reduced, the impedance is reduced. Therefore, there is an effect of reducing the potential fluctuation generated at the power terminal of the semiconductor device by the displacement current.

In the third embodiment, the power supply pad 303PV1 and the power supply pad 315PV1, the power supply pad 314PV1 and the power supply pad 317PV1, and the power supply pad 304PV1 and the power supply pad 316PV1 are formed as individual pads, but they may be formed as single pad. In this case, the power supply via 303VV and the power supply via 315VV, the power supply via 314VV and the power supply via 317VV, and the power supply via 304VV and the power supply via 316VV may be formed as one via instead of individual vias. This configuration also applies to the GND pad 304PG1, GND pad 314PG1, GND pad 316PG1, GND pad 317PG1, GND via 304VG, GND via 314VG, GND via 316VG, and GND via 317VG.

### Example 1

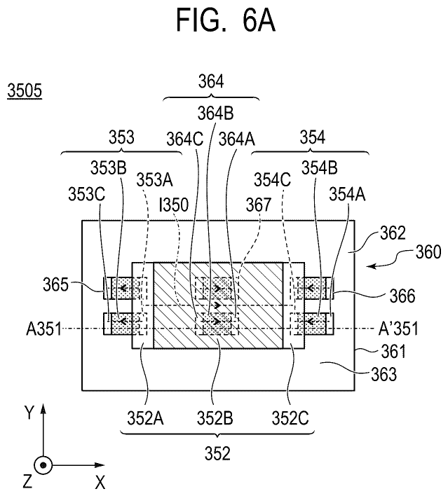

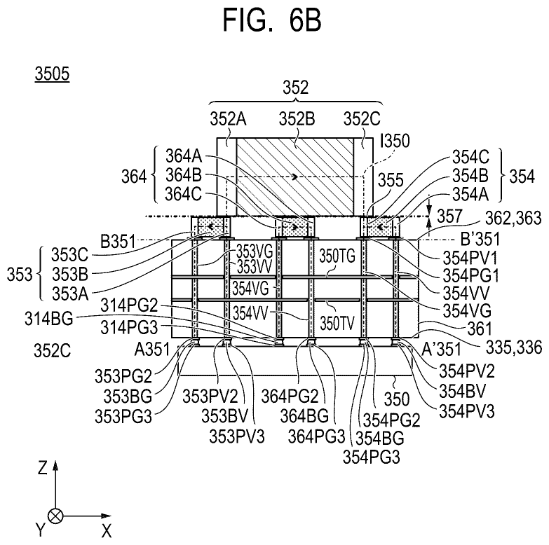

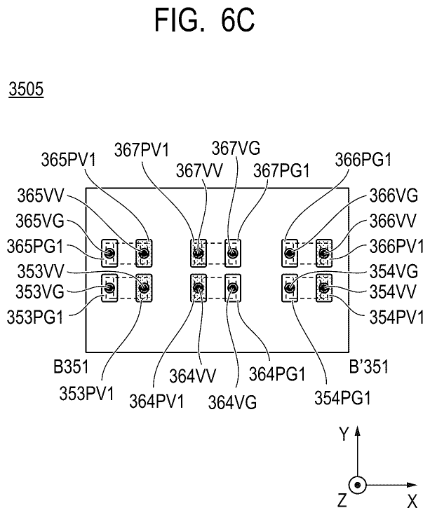

FIG. 6A is a plane view illustrating a processing module 3505 according to a comparative example to explain the effect of the third embodiment. FIG. 6B is a cross-sectional view of the XZ plane along a dotted line A351-A′351 in FIG. 6A. FIG. 6C is a cross-sectional view of the XY plane along a dotted line B351-B′351 in FIG. 6B. The differences between the comparative example and the third embodiment will be explained below.

As illustrated in FIG. 6A and FIG. 6B, in the comparative example, the placement of the conductive pads, power supply vias, and GND vias from each of the fourth chip component 364 and the seventh chip component 367 to the semiconductor device 350 is reversed from that of the third embodiment. Thereby, the directions of the currents of the fourth chip component 364 and the seventh chip component 367 are opposite to those of the third embodiment. Specifically, in plane view, the direction of the currents of the fourth chip component 364 is in the positive X-direction. Similarly, the direction of the currents of the seventh chip component 367 is in the positive X-direction. The second chip component 352 is stacked on the fourth chip component 364 and the seventh chip component 367. The direction of the currents 1350 in the second chip component 352 is in the positive X-direction. As described above, the comparative example differs from the third embodiment in that the directions of the currents of the fourth chip component 364 and the seventh chip component 367 are the same as the directions of the currents of the second chip component 352. In the configuration of the comparative example, since the currents of the chip components adjacent to each other are not opposed to each other, the action of canceling the generated magnetic field does not work.

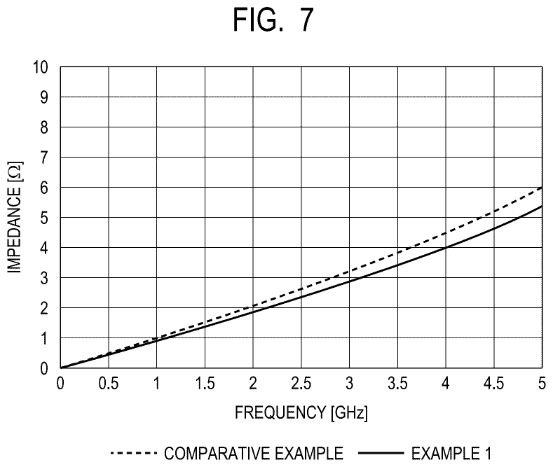

FIG. 7 is a diagram illustrating simulation results of the power supply impedance of an example 1 and the comparative example. In both the example 1 of the third embodiment and the comparative example, a multilayer ceramic capacitor having a component size of 0402 size and a capacitance of 0.1 off was used as the first chip component and the third to seventh chip components. As the second chip component, a multilayer ceramic capacitor having a component size of 1608 size and a capacitance of 10 if was used. The multilayer ceramic capacitor was mounted on a power supply pad and a GND pad formed on the main surface of a printed wiring board having a thickness of one mm. Then, the electric circuit of the multilayer ceramic capacitor was pulled out to the opposite side of the printed wiring board with a via having a diameter of 0.2 mm, and the impedance characteristics between the power supply and the GND were observed. “ANSYS Electronics Desktop 2021 R2” of ANSYS was used as the simulation tool. As illustrated in FIG. 7, the impedance of the example 1 according to the third embodiment was lower than that of the comparative example, and a reduction effect of 8.1% was confirmed at a frequency of 1 GHz, for example.

### Fourth Embodiment

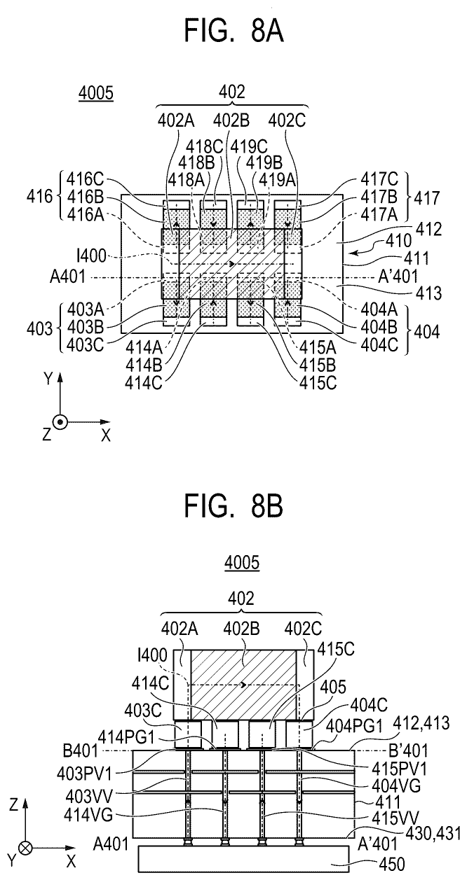

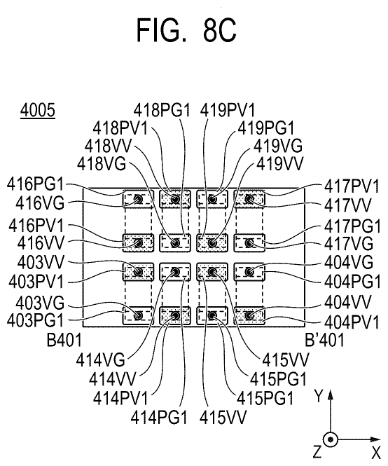

FIG. 8A is a plane view illustrating a processing module 4005 according to a fourth embodiment. FIG. 8B is a cross-sectional view of the XZ plane along a dotted line A401-A′401 in FIG. 8A. FIG. 8C is a cross-sectional view of the XY plane along a dotted line B401-B′401 in FIG. 8B. The differences between the fourth embodiment and the other embodiments will be mainly described below.

A semiconductor device 450 is an example of a load, such as an LSI package. In the fourth embodiment, a first chip component 403, a second chip component 402, a third chip component 404, a fourth chip component 414, a fifth chip component 415, a sixth chip component 416, a seventh chip component 417, an eighth chip component 418, and a ninth chip component 419 are capacitors. In the fourth embodiment, the size of the second chip component 402 is larger than the size of the other chip components (403, 404, 414, 415, 416, 417, 418, 419). For example, the second chip component 402 is a chip component of 1608 size. The chip components other than the second chip component 402 are 0.6 mm×0.3 mm in size (Hereinafter referred to as “0603 size”). The first chip component 403 and from the third chip component 404 to the ninth chip component 419 are disposed so that the longitudinal direction is perpendicular to the longitudinal direction (X-direction) of the second chip component 402.

In FIG. 8A and FIG. 8B, the direction of the current in the processing module 4005 is indicated by a dotted line 1400. Among the first chip component 403, the third chip component 404, the fourth chip component 414, the fifth chip component 415, the sixth chip component 416, the seventh chip component 417, the eighth chip component 418, and the ninth chip component 419, currents on the capacitors adjacent to each other in the X-direction or the Y-direction face each other. For example, in FIG. 8A, the direction of the current in the first chip component 403 is in the negative Y-direction. The first chip component 403 is adjacent to the fourth chip component 414 in the X-direction and the sixth chip component 416 in the Y-direction. The direction of the current in the fourth chip component 414 is in the positive Y-direction. Similarly, the direction of the current in the sixth chip component 416 is in the positive Y-direction. Since opposing currents work to cancel each other's magnetic fields, parasitic inductance (=ESL) of the capacitor can be reduced.

As illustrated in FIG. 8B, when adjacent capacitors are disposed so that the current faces each other, the direction of the current also faces each other in the adjacent power supply via and GND via. For example, in FIG. 8B, the direction of the current in the GND via 414VG of the fourth chip component 414 is in the negative Z-direction. On the other hand, the direction of the current in the power supply via 415VV of the fifth chip component 415 is in the positive Z-direction. Since opposing currents work to cancel each other's magnetic fields, the inductance of the power supply via and the GND via can be reduced.

### Example 2

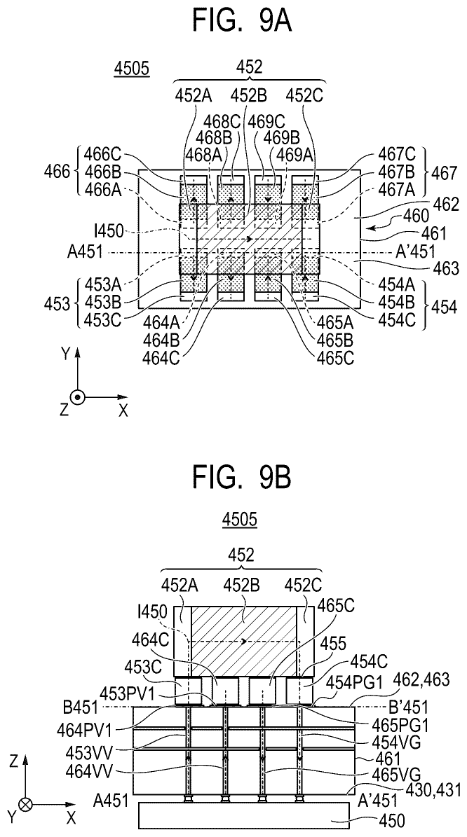

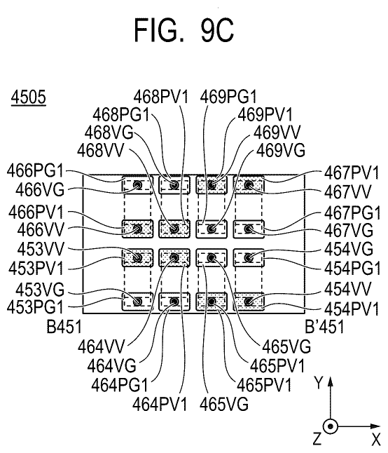

FIG. 9A is a plane view illustrating a processing module 4505 according to the comparative example to explain the effect of the fourth embodiment. FIG. 9B is a cross-sectional view of the XZ plane along a dotted line A451-A′451 in FIG. 9A. FIG. 9C is a cross-sectional view of the XY plane along a dotted line B451-B′451 in FIG. 9B. The differences between the comparative example and the fourth embodiment will be explained below.

As illustrated in FIG. 9A and FIG. 9B, in the comparative example, the placement of the conductive pads, power supply vias, and GND vias from the fourth chip component 464, the fifth chip component 465, the eighth chip component 468, and the ninth chip component 469 to the semiconductor device 450 is reversed from the placement in the fourth embodiment. Thereby, the directions of currents in the fourth chip component 464, the fifth chip component 465, the eighth chip component 468, and the ninth chip component 469 are reversed from the directions of currents in the fourth embodiment. As a result, in the comparative example, the canceling action of the magnetic field does not work between components (between the first chip component 453 and the fourth chip component 464, between the third chip component 454 and the fifth chip component 465, between the sixth chip component 466 and the eighth chip component 468, and between the seventh chip component 467 and the ninth chip component 469) adjacent to each other.

Similarly, between components (between the first chip component 453 and the fourth chip component 464, between the third chip component 454 and the fifth chip component 465, between the sixth chip component 466 and the eighth chip component 468, and between the seventh chip component 467 and the ninth chip component 469) adjacent to each other, the canceling action of the magnetic field between the power supply vias and the GND vias does not work.

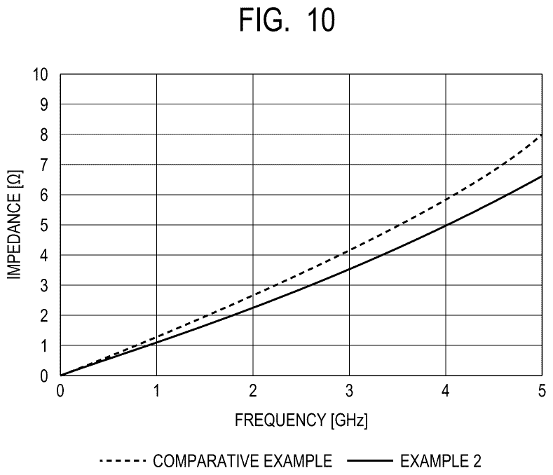

FIG. 10 is a diagram illustrating the simulation results of the power supply impedance of the example 2 and the comparative example. In both example 2 and comparative example according to the fourth embodiment, a multilayer ceramic capacitor having a component size of 0603 size and a capacitance of 0.1 if was used as the first chip component and the third to ninth chip components. A multilayer ceramic capacitor with a component size of 1608 size and a capacitance of 10 μF was used as the second chip component. The multilayer ceramic capacitor was mounted on a power supply pad and a GND pad formed on the main surface of a printed wiring board having a thickness of one mm. Then, the electrical circuit of the multilayer ceramic capacitor was pulled out to the opposite surface of the printed wiring board by a via having a diameter of 0.2 mm, and the impedance characteristics between the power supply and the GND were observed. As illustrated in FIG. 10, the impedance of the example 2 according to the fourth embodiment was lower than that of the comparative example, and a reduction effect of 13.7% was confirmed when the frequency was one GHz, for example.

### Fifth Embodiment

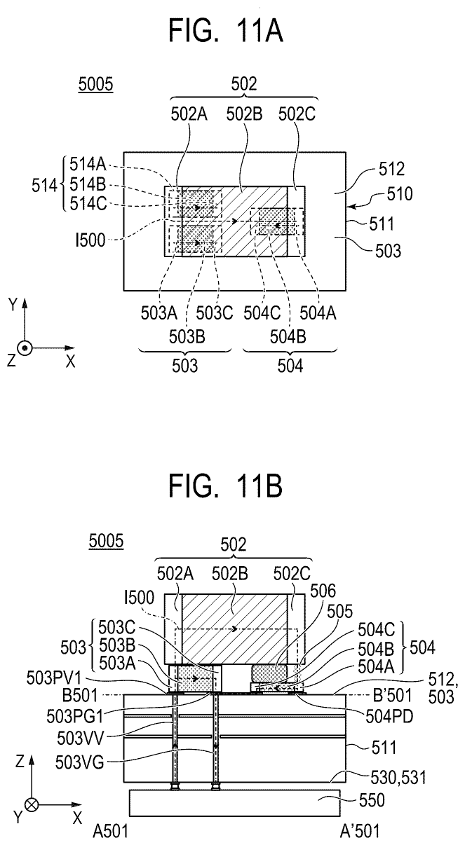

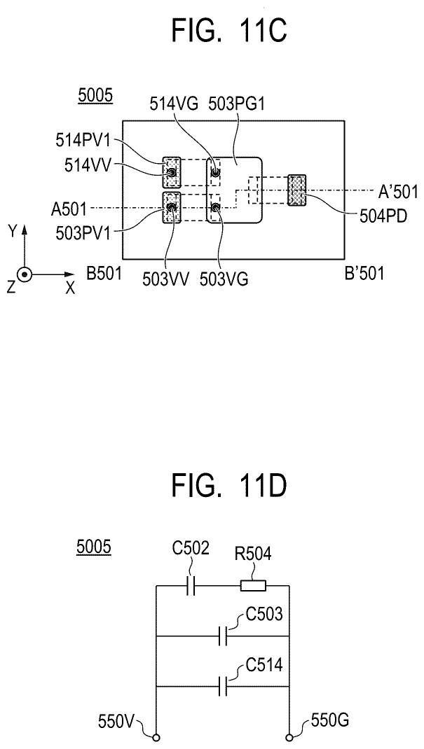

FIG. 11A is a plane view illustrating a processing module 5005 according to a fifth embodiment. FIG. 11B is a cross-sectional view of the XZ plane along a dotted line A501-A′501 in FIG. 11C. FIG. 11C is a cross-sectional view of the XY plane along a dotted line B501-B′501 in FIG. 11B. FIG. 11D is a diagram illustrating the processing module 5005 according to the fifth embodiment represented by an equivalent circuit. The differences between the fifth embodiment and the other embodiments will be mainly described below.

A first chip component 503, a second chip component 502, and a fourth chip component 514 are capacitors in the fifth embodiment. A third chip component 504 is a chip resistor in the fifth embodiment. In the fifth embodiment, the size of the second chip component 502 is larger than the sizes of the first chip component 503, the third chip component 504, and the fourth chip component 514. For example, the first chip component 503, the third chip component 504, and the fourth chip component 514 are chip components of 0603 size, and the second chip component is a chip component of 1608 size. In the Z-direction of FIG. 11B, the height of the third chip component 504 is lower than the height of the first chip component 503 and the fourth chip component 514. Therefore, in the fifth embodiment, a spacer 506 is disposed between the second chip component 502 and the third chip component 504 for adjusting the height between the components. The spacer 506 is a non-conductive member. The spacer 506 may be omitted.

The fourth electrode portion 502C of the second chip component 502 and the fifth electrode portion 504A of the third chip component 504 are connected to each other by a conductive adhesive 505 such as solder. The second electrode portion 503C of the first chip component 503 and the sixth electrode portion 504C of the third chip component 504 are connected via a GND pad 503PG1.

The fifth electrode portion 504A of the third chip component 504 is fixed to the dummy pad 504PD with a conductive adhesive 505. The fifth electrode portion 504A of the third chip component 504 may be in contact with the dummy pad 504PD without the conductive adhesive 505. The dummy pad 504PD may be omitted.

In FIG. 11A and FIG. 11B, the direction of the current in the processing module 5005 is indicated by dotted lines. For example, a dotted line 1500 indicates the direction of the current in the second chip component 502.

In FIG. 11D, a plurality of chip components is connected in parallel between the power terminal 550V and the GND terminal 550G of the semiconductor device 550. A capacitor C502 is the second chip component 502, a capacitor C503 is the first chip component 503, a capacitor C514 is the fourth chip component 514, and a chip resistor R504 is the third chip component 504.

As illustrated in FIG. 11A to FIG. 11D, in the fifth embodiment, a chip resistor R504 is connected in series to the capacitor C502. The effect of the chip resistor R504 will be described below. In a circuit in which a plurality of capacitors is connected in parallel, an anti-resonance phenomenon occurs, and the impedance increases at the anti-resonance frequency. The peak increase of the impedance causes potential fluctuation of the power supply, which may lead to an operation failure of the semiconductor device. The anti-resonance frequency and the peak size are determined by the capacitance value, the internal parasitic inductance value, and the internal resistance value of each capacitor, and the inductance value and the resistance value of the wiring between the capacitors. One method of reducing the peak value of anti-resonance is to increase the resistance value of the wiring between the capacitors. The chip resistor R504 is added to increase the resistance value of the wiring between the capacitors.

### Example 3

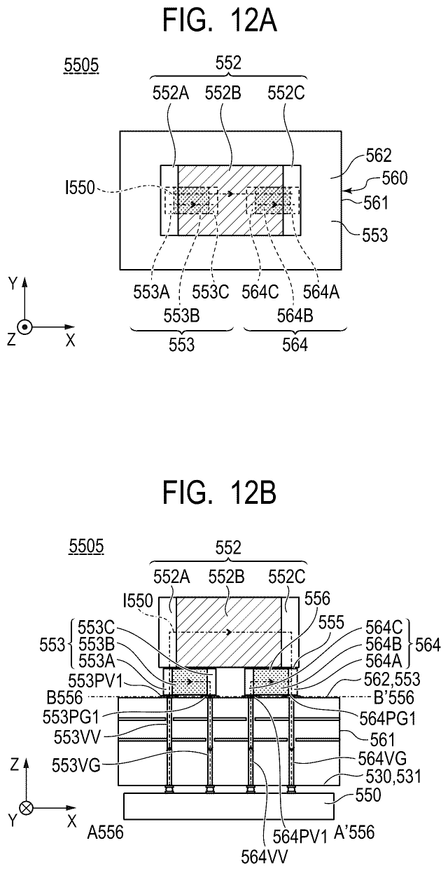

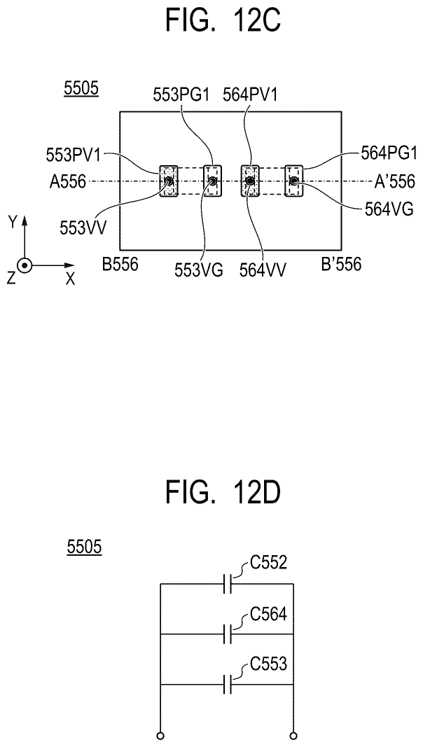

FIG. 12A is a plane view illustrating a processing module 5505 according to a comparative example for explaining the effect of the fifth embodiment. FIG. 12B is a cross-sectional view of the XZ plane along a dotted line A556-A′556 in FIG. 12C. FIG. 12C is a cross-sectional view of the XY plane along a dotted line B551-B′551 in FIG. 12B. FIG. 12D is a diagram illustrating the processing module 5505 according to the comparative example represented by an equivalent circuit. The differences between the comparative example and the fifth embodiment will be explained below.

The comparative example differs from the fifth embodiment in that the third chip component 504 (chip resistor R504) illustrated in FIGS. 11A to 11D is not present in the circuit. In addition, the comparative example differs from the fifth embodiment in the positions of the first chip component 553 and the fourth chip component 564, which are capacitors, and the positions of the power supply pad, GND pad, and via connected to each capacitor. The placement in the comparative example is the same as that in the first embodiment described above.

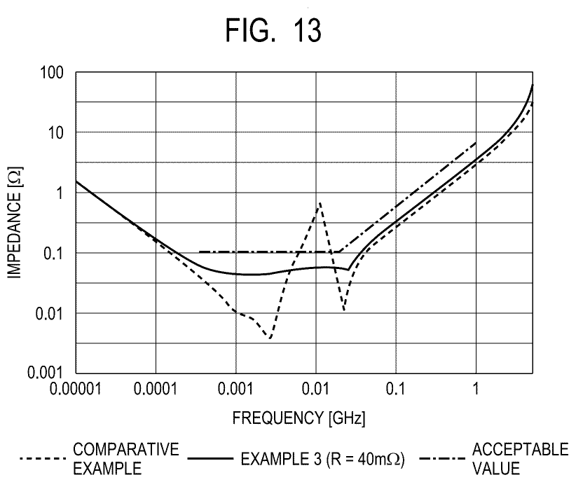

FIG. 13 is a diagram illustrating the simulation results of the power supply impedance of the example 3 according to the fifth embodiment and the comparative example. A multilayer ceramic capacitor having a component size of 0603 size and a capacitance of 0.1 μF was used as the first and fourth chip components. As the second chip component, a multilayer ceramic capacitor having a component size of 1608 size and a capacitance of 10 μF was used. As the fourth chip component, a chip resistor having a component size of 0603 size and an electrical resistance of 40 mΩ was used. The multilayer ceramic capacitor was mounted on a power supply pad and a GND pad formed on the main surface of a printed wiring board having a thickness of one mm. The electrical circuit of the multilayer ceramic capacitor was pulled out to the opposite surface of the printed wiring board with a via having a diameter of 0.2 mm, and the impedance characteristics between the power supply and the GND were observed.

As illustrated in FIG. 13, in the comparative example, an anti-resonance peak was observed at a frequency near 0.01 GHz. On the other hand, in the example 3 of the fifth embodiment, the anti-resonance peak detected in the comparative example was reduced. Generally, a tolerance value is set for each frequency as the impedance characteristic of the power supply in a semiconductor device. The tolerance value is determined according to the operating frequency of the semiconductor device and the sensitivity to external noise. Assuming that the tolerance value indicated by the dotted line in FIG. 13 is set, the calculated value in the comparative example exceeds the tolerance value, while the calculated value in the example 3 satisfies the tolerance value.

### Sixth Embodiment

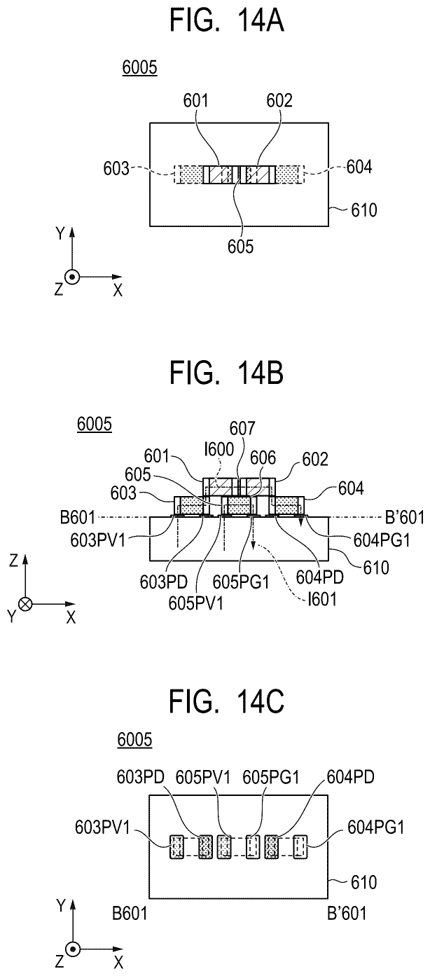

FIG. 14A is a plane view illustrating a processing module 6005 according to a sixth embodiment. FIG. 14B is a side view illustrating the processing module 6005. FIG. 14C is a cross-sectional view of the XY plane along a dotted line B601-B′601 in FIG. 14B. The differences between the sixth embodiment and the other embodiments will be mainly described below.

In the sixth embodiment, a second chip component 602, a third chip component 604, a fourth chip component 603, and a fifth chip component 601 are chip resistors. A first chip component 605 is a capacitor. In the sixth embodiment, the sizes of the first to fifth chip components are all the same. The first to fifth chip components are, for example, chip components of 0402 size.

The first chip component 605, the third chip component 604, and the fourth chip component 603 are mounted on the main surface of a printed wiring board 610. A dummy pad 603PD and a dummy pad 604PD are provided between the first chip component 605, the third chip component 604, and the fourth chip component 603 and the printed wiring board 610.

The second chip component 602 and the fifth chip component 601 are stacked on the first chip component 605. A non-conductive member 606 is provided between the first chip component 605 and the second chip component 602 and the fifth chip component 601. The second chip component 602 is connected to the fifth chip component 601 by a conductive adhesive 607.

The electrode portions at both ends of the first chip component 605 overlap the non-electrode portions of the fifth chip component 601 and the non-electrode portions of the second chip component 602 in the plane view along the Z-direction. The electrode portions of the first chip component 605 are electrically isolated from the electrode portions of the fifth chip component 601 and the second chip component 602. On the other hand, the fourth chip component 603, the fifth chip component 601, the second chip component 602, and the third chip component 604 are connected via the conductive adhesive 607. In other words, the first chip component 605 is not electrically connected to any of the fourth chip component 603, the fifth chip component 601, the second chip component 602, and the third chip component 604. As described above, according to the sixth embodiment, the chip components that are not connected to each other can be disposed so that the electrode portions and the non-electrode portions overlap. Thereby, circuits can be formed separately in the Z-direction.

### Seventh Embodiment

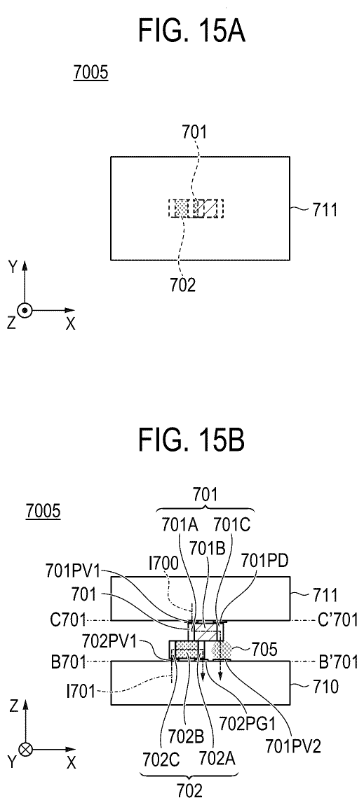

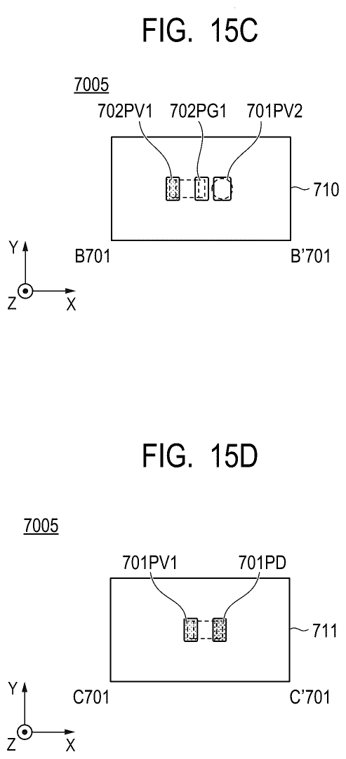

FIG. 15A is a plane view illustrating a processing module 7005 according to a seventh embodiment. FIG. 15B is a side view illustrating the processing module 7005. FIG. 15C is a cross-sectional view of the XY plane along a dotted line B701-B′701 in FIG. 15B. FIG. 15D is a cross-sectional view of the XY plane along a dotted lines C701-C′701 in FIG. 15B. The differences between the seventh embodiment and the other embodiments will be mainly described below.

In the seventh embodiment, a first chip component 702 and a second chip component 701 are chip components of the same size. The first chip component 702 and the second chip component 701 are, for example, capacitors of 0402 size. Electrode portions at both ends of the first chip component 702 are connected to a power supply pad 702PV1 and a GND pad 702PG1 formed on a printed wiring board 710. Electrode portions at both ends of the second chip component 701 are connected to the power supply pad 701PV1 and a dummy pad 701PD formed on the printed wiring board 711.

In addition, one of the electrodes (electrode in the negative X-direction in the figure) at both ends of the first chip component 702 is connected to the power supply pad 701PV2 formed on the printed wiring board 710 via a conductive adhesive 705 such as solder. The other electrode (electrode in the positive X-direction in the figure) of the first chip component 702 is connected to the power supply pad 701PV1 formed on the printed wiring board 711. As illustrated in FIG. 15B, two chip components are sandwiched between two printed wiring boards 710 and 711. Here, a dotted line 1700 indicates the direction of the current flowing through the printed wiring board 711, the second chip component 701, the conductive adhesive 705, and the printed wiring board 710.

As described above, according to the seventh embodiment, the electrode portion of the second chip component 701 is disposed to overlap with the non-electrode portion of the first chip component 702 in the Z-direction. Thereby, it is possible to separately construct a circuit across the upper and lower printed wiring boards 710 and 711 and a circuit closed between the printed wiring board 710 and the first chip component 702 in a narrow region.

### Eighth Embodiment

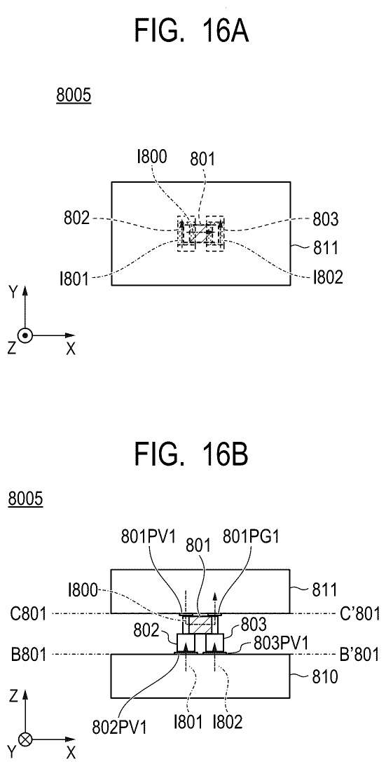

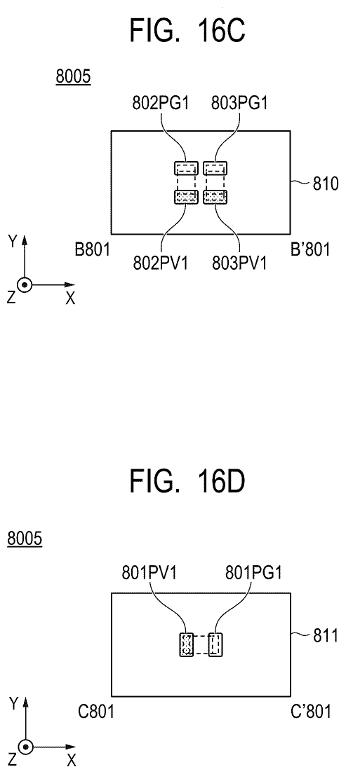

FIG. 16A is a plane view illustrating a processing module 8005 according to an eighth embodiment. FIG. 16B is a side view illustrating the processing module 8005. FIG. 16C is a cross-sectional view of the XY plane along a dotted line B801-B′801 in FIG. 16B. FIG. 16D is a cross-sectional view of the XY plane along a dotted line C801-C′801 in FIG. 16B. The differences between the eighth embodiment and other embodiments will be mainly described below.

In the eighth embodiment, the first chip component 802, the second chip component 801, and the third chip component 803 are chip components of the same size, for example, capacitors of 0402 size. Electrodes of the first chip component 802 and the third chip component 803 is respectively connected to a power supply pad 802PV1, a GND pad 802PG1, a power supply pad 803PV1, and a GND pad 803PG1 formed on the printed wiring board 810. The dotted line 1801 indicates that current flows from the printed wiring board 810 to the first chip component 802 and returns to the printed wiring board 810. Similarly, the dotted line 1802 indicates that current flows from the printed wiring board 810 to the third chip component 803 and returns to the printed wiring board 810.

Electrode portions at both ends of the second chip component 801 are connected to a power supply pad 801PV1 and a GND pad 801PG1 formed on the printed wiring board 811, respectively. Electrode portions at both ends of the second chip component 801 are disposed on the non-electrode portion of the first chip component 802 and the non-electrode portion of the third chip component 803, respectively. Electrode portions at both ends of the second chip component 801 are electrically connected to a power supply pad 801PV1 and a GND pad 801PG1 formed on the printed wiring board 811, respectively. As illustrated in FIG. 16B, three chip components are sandwiched between two printed wiring boards 810 and 811. A dotted line 1800 indicates that current flows from the printed wiring board 811 to the second chip component 801 and returns to the printed wiring board 811.

According to the eighth embodiment, the two electrode portions of the second chip component 801 are disposed so as to overlap the non-electrode portion of the first chip component 802 and the non-electrode portion of the third chip component 803, respectively. Thereby, circuits can be formed separately in the Z-direction. The circuits can be formed without the conductive adhesive used in the seventh embodiment.

### Ninth Embodiment

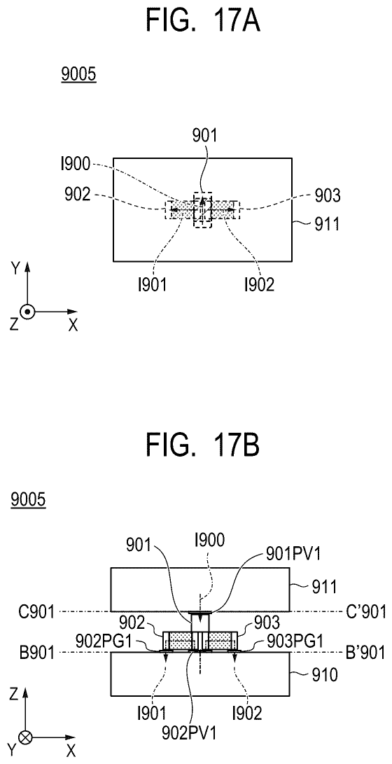

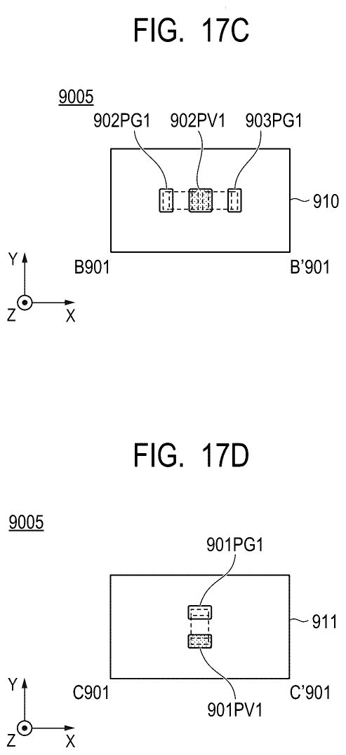

FIG. 17A is a plane view illustrating a processing module 9005 according to a ninth embodiment. FIG. 17B is a side view illustrating the processing module 9005 according to the ninth embodiment. FIG. 17C is a cross-sectional view of the XY plane along a dotted line B901-B′901 in FIG. 17B. FIG. 17D is a cross-sectional view of the XY plane along a dotted line C901-C′901 in FIG. 17B. The differences between the ninth embodiment and the other embodiments will be mainly described below.

In the ninth embodiment, a first chip component 902, a second chip component 901, and a third chip component 903 are chip components of the same size, for example, capacitors of 0402 size. The electrode portions of the first chip component 902 and the third chip component 903 are connected to a power supply pad 902PV1, a GND pad 902PG1, and a GND pad 902PG1 formed on a printed wiring board 910, respectively. The electrode portions of the second chip component 901 are connected to a power supply pad 901PV1 and a GND pad 901PG1 formed on a printed wiring board 911, respectively.

As illustrated in FIG. 17B, three chip components are sandwiched between the two printed wiring boards 910 and 911. By disposing the electrodes of the second chip component 901 so as to overlap the electrode portion of the first chip component 902 and the non-electrode portion of the third chip component 903, circuits can be formed separately in the Z-direction. The ninth embodiment differs from the eighth embodiment in the component placement of the lower printed wiring board 910. As described above, according to the ninth embodiment, a layout can be flexible.

### Tenth Embodiment

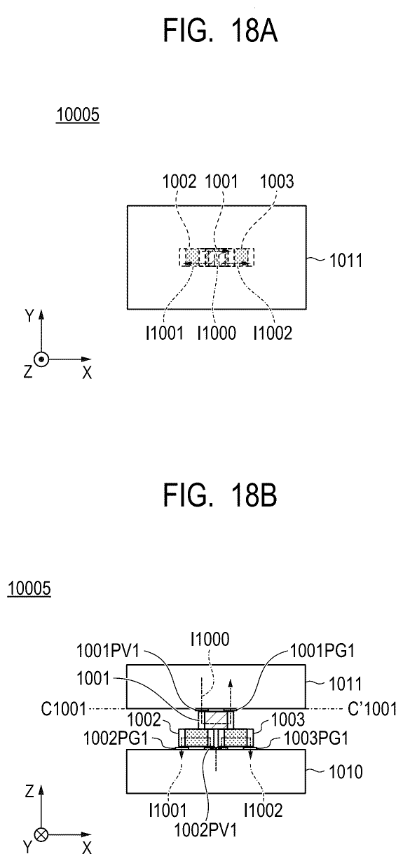

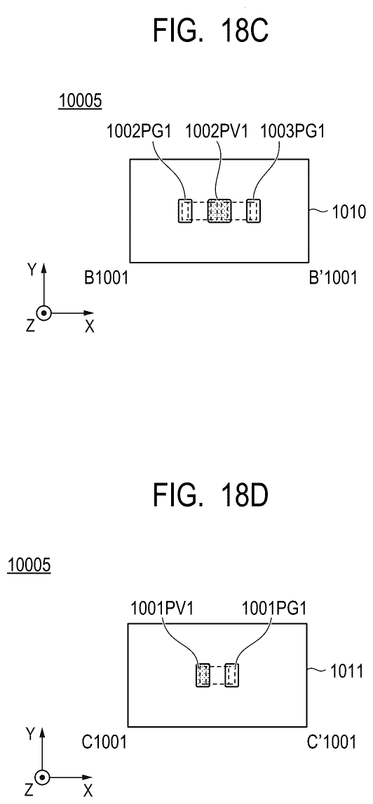

FIG. 18A is a plane view illustrating a processing module 10005 according to a tenth embodiment. FIG. 18B is a side view illustrating the processing module 10005. FIG. 18C is a cross-sectional view of the XY plane along a dotted line B1001-B′1001 in FIG. 18B. FIG. 18D is a cross-sectional view of the XY plane along a dotted line C1001-C′1001 in FIG. 18B. The differences between the tenth embodiment and the other embodiments will be mainly described below.

In the tenth embodiment, a first chip component 1002, a second chip component 1001, and a third chip component 1003 are chip components of the same size, for example, capacitors of 0402 size. The electrode portions of the first chip component 1002 are connected to a power supply pad 1002PV1 and a GND pad 1002PG1 formed on a printed wiring board 1010. The electrode portions of the third chip component 1003 are connected to the power supply pads 1002PV1 and 1003PG1 formed on the printed wiring board 1010. That is, the electrode portions of the two chip components are connected to the power supply pad 1002PV1. The electrode portions of the second chip component 1001 are connected to a power supply pad 1001PV1 and a GND pad 1001PG1 formed on an upper printed wiring board 1011. As illustrated in FIG. 18B, the three chip components are sandwiched between the two printed wiring boards 1010 and 1011.

As described above, by disposing the electrode portions of the second chip component 1001 so as to overlap the non-electrode portions of the first chip component 1002 and the non-electrode portions of the third chip component 1003, circuits can be formed separately in the Z-direction. In the tenth embodiment, the component placement on the upper printed wiring board 1011 is different from the ninth embodiment, and the projected area of the chip components seen from the Z-direction can be smaller than the ninth embodiment. Therefore, the flexibility of layout is improved.

### Eleventh Embodiment

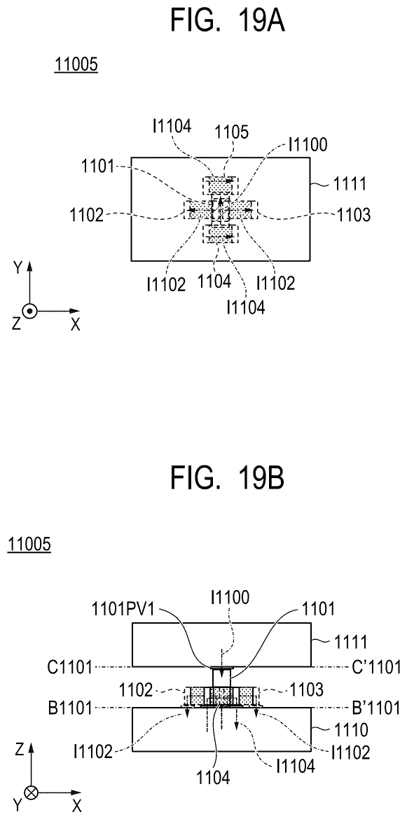

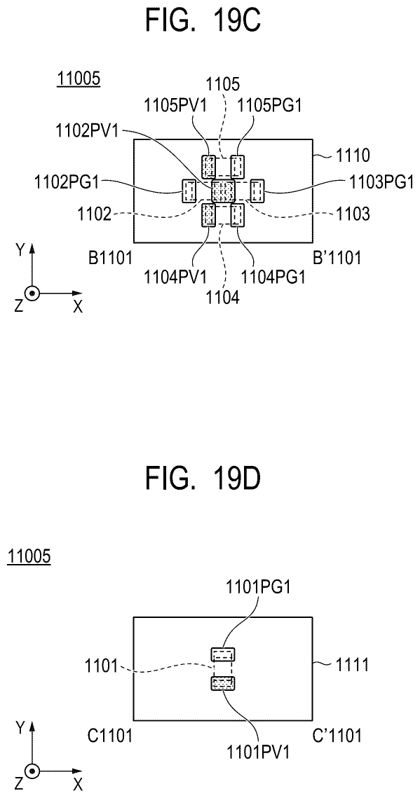

FIG. 19A is a plane view illustrating a processing module 11005 according to an eleventh embodiment. FIG. 19B is a side view illustrating the processing module 11005. FIG. 19C is a cross-sectional view of the XY plane along a dotted line B1101-B′1101 in FIG. 19B. FIG. 19D is a cross-sectional view of the XY plane along a dotted line C1101-C′1101 in FIG. 19B. The differences between the eleventh embodiment and the other embodiments will be mainly described below.

In the eleventh embodiment, a first chip component 1102, a second chip component 1101, a third chip component 1103, a fourth chip component 1104, and a fifth chip component 1105 are chip components of the same size, for example, capacitors of 0402 size. The electrode portions of the first chip component 1102, the third chip component 1103, the fourth chip component 1104, and the fifth chip component 1105 are respectively connected to power supply pads 1102PV1, 1104PV1, 1105PV1, GND pads 1102PG1, 1103PG1, 1104PG1, and 1105PG1 formed on a printed wiring board 1110.

The electrode portions of the second chip component 1101 are connected to a power supply pad 1101PV1 and a GND pad 1101PG1 formed on a printed wiring board 1111. As illustrated in FIG. 19A and FIG. 19B, five chip components are sandwiched between the two printed wiring boards 1110 and 1111. The chip components are disposed so that the two electrode portions of the second chip component 1101 overlap any of the non-electrode portions of the first chip component 1102, the third chip component 1103, the fourth chip component 1104, and the fifth chip component 1105, and the electrode portions of the first chip component 1102, the third chip component 1103, the fourth chip component 1104, and the fifth chip component 1105 overlap the non-electrode portions of the second chip component in the plane view. Thereby, circuits can be formed separately in the Z-direction. In the eleventh embodiment, more chip components can be mounted, and the flexibility of layout is improved as compared with the tenth embodiment.

### Twelfth Embodiment

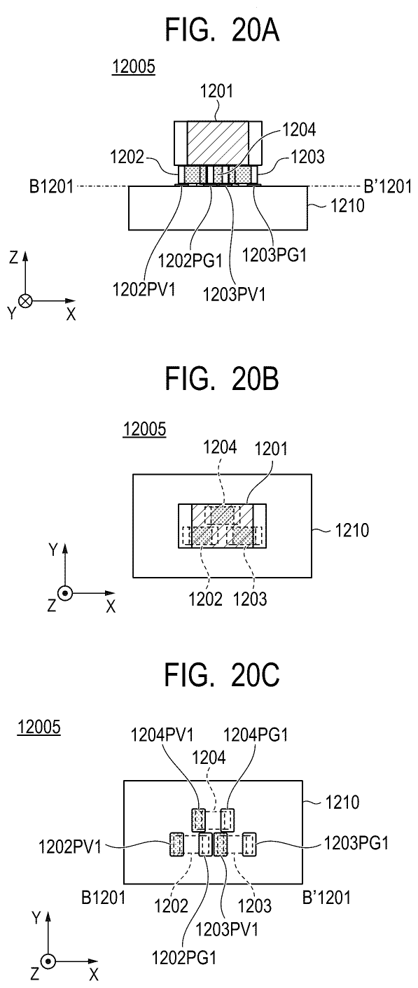

FIG. 20A is a side view illustrating a processing module 12005 according to a twelfth embodiment. FIG. 20B is a plane view illustrating the processing module 12005. FIG. 20C is a cross-sectional view of the XY plane along a dotted line B1201-B′1201 in FIG. 20A. The differences between the twelfth embodiment and the other embodiments will be mainly described below.

In the twelfth embodiment, a first chip component 1202, a third chip component 1203, and a fourth chip component 1204 are chip components of the same size, for example, capacitors of 0402 size. The second chip component 1201 is, for example, capacitors of 1005 size.

One electrode portion (electrode portion in the negative X-direction in the figure) of the first chip component 1202 is connected to one electrode portion (electrode portion in the negative X-direction in the figure) of the second chip component 1201. Similarly, one electrode portion (electrode portion in the positive X-direction in the figure) of the third chip component 1203 is connected to the other electrode portion (electrode portion in the positive X-direction in the figure) of the second chip component 1201. This configuration is the same as that of the first embodiment. In the twelfth embodiment, the fourth chip component 1204 is disposed adjacent to the first chip component 1202 and the third chip component 1203. None of the electrode portions at both ends of the fourth chip component 1204 is connected to the electrode portions of other components.

As illustrated in FIG. 20C, on a printed wiring board 1210, the fourth chip component 1204 is disposed so as to be positioned in the Y-direction more than the first chip component 1202 and the third chip component 1203 and straddling the first chip component 1202 and the third chip component 1203 in the X-direction. Thereby, the first chip component 1202, the third chip component 1203, and the fourth chip component 1204 are disposed more in the longitudinal direction than in the short direction of the second chip component 1201. According to the twelfth embodiment, one more chip component is mounted than in the first embodiment in the same area as in the first embodiment, and the flexibility of layout is further improved.

### Thirteenth Embodiment

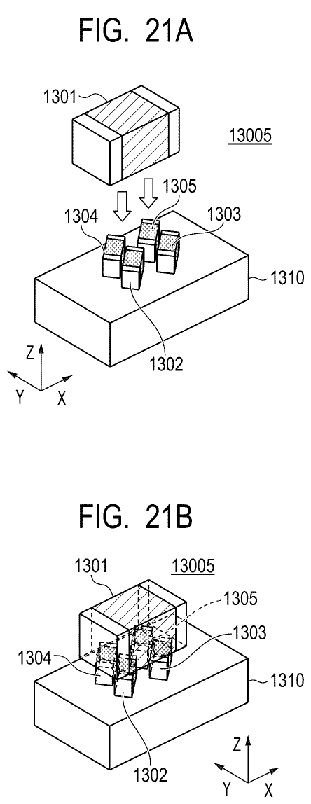

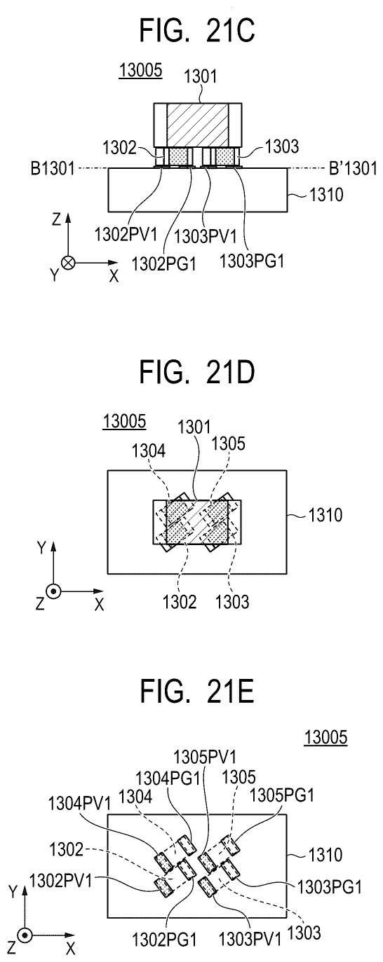

FIG. 21A and FIG. 21B are perspective views for explaining the manufacturing process of a processing module 13005 according to a thirteenth embodiment. FIG. 21C is a side view illustrating the processing module 13005. FIG. 21D is a plane view illustrating the processing module 13005. FIG. 21E is a cross-sectional view of the XY plane along a dotted line B1301-B′1301 in FIG. 21C. The differences between the thirteenth embodiment and the other embodiments will be mainly described below.

In the thirteenth embodiment, a first chip component 1302, a third chip component 1303, a fourth chip component 1304, and a fifth chip component 1305 are chip components of the same size, for example, capacitors of 0402 size. The second chip component 1301 is, for example, capacitors of 1005 size.

In the first chip component 1302, an electrode in the positive X-direction is set as a first electrode portion, an electrode in the negative X-direction is set as a second electrode portion, and a portion between the two electrode portions is set as a first non-electrode portion. A second chip component 1301, an electrode in the positive X-direction is set as a third electrode portion, an electrode in the negative X-direction is set as a fourth electrode portion, and a portion between the two electrode portions is set as a second non-electrode portion. In the third chip component 1303, an electrode in the positive X-direction is set as a fifth electrode portion, an electrode in the negative X-direction is set as a sixth electrode portion, and a portion between the two electrode portions is set as a third non-electrode portion. In the fourth chip component 1304, an electrode in the positive X-direction is set as a seventh electrode portion, an electrode in the negative X-direction is set as an eighth electrode portion, and a space between the two electrode portions is set as a fourth non-electrode portion. In the fifth chip component 1305, an electrode in the positive X-direction is a ninth electrode portion, an electrode in the negative X-direction is set as a tenth electrode portion, and a portion between the two electrode portions is set as a fifth non-electrode portion.

As illustrated in FIG. 21A, the first chip component 1302, the third chip component 1303, the fourth chip component 1304, and the fifth chip component 1305 are disposed on a printed wiring board 1310. Next, the second chip component 1301 is stacked on the first chip component 1302, the third chip component 1303, the fourth chip component 1304, and the fifth chip component 1305. At this time, as illustrated in FIG. 21B, the longitudinal sides of the first chip component 1302, the third chip component 1303, the fourth chip component 1304, and the fifth chip component 1305 and the longitudinal sides of the second chip component 1301 are disposed so as to intersect at a predetermined angle. Thereby, each of the second electrode portion, the sixth electrode portion, the seventh electrode portion, the eighth electrode portion, and the ninth electrode portion partially protrude from the second non-electrode portion of the second chip component 1301 in the plane view. Each of the third electrode portion and the fourth electrode portion partially protrudes from the first non-electrode portion, the third non-electrode portion, the fourth non-electrode portion, and the fifth non-electrode portion in the plane view. Thereby, the occupied area of the plurality of chip components is reduced in the plane view, and a plurality of electric circuits are constructed between the printed wiring board 1310 and the chip components by the stacked structure of the chip components.

According to the thirteenth embodiment, the number of components to be disposed on the mounting surface of the printed wiring board 1310 can be increased. In the thirteenth embodiment, for example, compared with the first embodiment, one more chip component can be disposed on the mounting surface of the same area.

### Fourteenth Embodiment

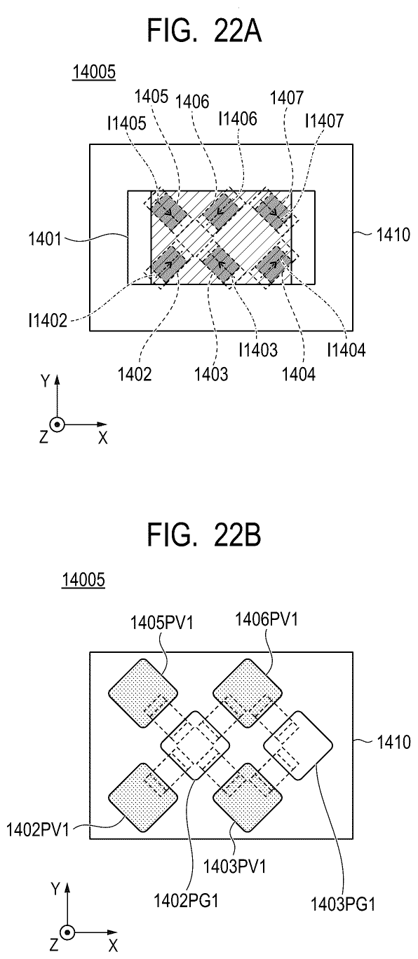

FIG. 22A is a plane view illustrating a processing module 14005 according to a fourteenth embodiment. FIG. 22B is a cross-sectional view along the XY plane of the processing module 14005. The differences between the fourteenth embodiment and the other embodiments will be mainly described below.

A first chip component 1402, a third chip component 1403, a fourth chip component 1404, a fifth chip component 1405, a sixth chip component 1406, and a seventh chip component 1407 are chip components of the same size, for example, capacitors of 0402 size. The second chip component 1401 is a chip component larger than the other chip components, for example, capacitors of 1608 size.

The longitudinal sides of the chip components of the first chip component 1402, the fourth chip component 1404, and the sixth chip component 1406 are disposed so as to be parallel. On the other hand, the longitudinal sides of the chip components of the third chip component 1403, the fifth chip component 1405, and the seventh chip component 1407 are disposed so as to be parallel. The longitudinal sides of the chip components of the first chip component 1402, the fourth chip component 1404, and the sixth chip component 1406 and the longitudinal sides of the chip components of the third chip component 1403, the fifth chip component 1405, and the seventh chip component 1407 intersect at a predetermined angle. For example, in FIG. 22A, the longitudinal sides of the first chip component 1402 intersect with the longitudinal sides of the adjacent third chip component 1403 at an angle of 90 degrees.

Furthermore, the longitudinal sides of the second chip component 1401 intersect at an angle half of the angle formed by the longitudinal sides of the two sets of chip capacitors. The angle at which the two sides intersect is, for example, 45 degrees. Power supply pad 1402PV1 is a power supply pad for connecting the electrodes of the first chip component 1402. A GND pad 1402PG1 is a common GND pad for connecting the electrodes of the first chip component 1402, the third chip component 1403, the fifth chip component 1405, and the sixth chip component 1406.

A power supply pad 1403PV1 is a common power supply pad for connecting the electrodes of the third chip component 1403 and the fourth chip component 1404. A GND pad 1403PG1 is a common GND pad for connecting the electrodes of the fourth chip component 1404 and the seventh chip component 1407. A power supply pad 1405PV1 is a power supply pad for connecting the electrodes of the fifth chip component 1405. A power supply pad 1406PV1 is a common power supply pad for connecting the electrodes of the sixth chip component 1406 and the seventh chip component 1407, respectively.

Each of the electrode portions of the first chip component 1402 and the fifth chip component 1405 connected to the power supply pads 1402PV1 and 1405PV1 is connected to one of the electrode portions of the second chip component 1401 piled up thereon. Furthermore, each of the electrode portions of the fourth chip component 1404 and the seventh chip component 1407 connected to the GND pad 1403PG1 is connected to the other electrode of the second chip component 1401 piled up thereon.

With the above configuration, the number of mounted components can be increased. In addition, as can be seen from the direction of the current indicated by arrows in FIG. 22A, since the currents of the chip components facing in parallel are reversed and cancel each other, the inductance can be reduced.

### Fifteenth Embodiment

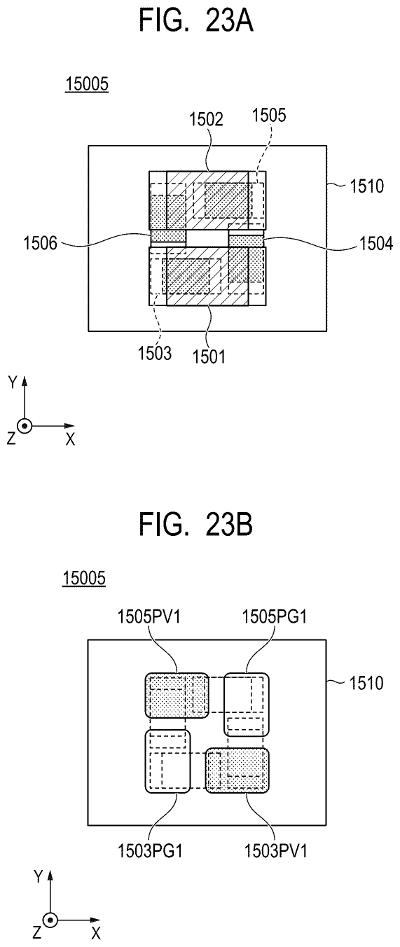

FIG. 23A is a plane view illustrating a processing module 15005 according to a fifteenth embodiment. FIG. 23B is a cross-sectional view of the processing module 15005 in the XY plane. The differences between the fifteenth embodiment and the other embodiments will be mainly described below.

A first chip component 1503, a third chip component 1504, a fourth chip component 1505, and a fifth chip component 1506 are chip components of the same size, for example, capacitors of 0603 size. The second chip component 1501 and the sixth chip component 1502 are capacitors of 1005 size, for example.

The power supply pad 1503PV1 is a common power supply pad for connecting the electrode portions of the first chip component 1503 and the third chip component 1504, respectively. A GND pad 1503PG1 is a common GND pad for connecting the electrodes of the first chip component 1503 and the fifth chip component 1506, respectively. A power supply pad 1505PV1 is a common power supply pad for connecting the electrode portions of the fourth chip component 1505 and the fifth chip component 1506, respectively. A GND pad 1505PG1 is a common GND pad for connecting the electrode portions of the third chip component 1504 and the fourth chip component 1505, respectively.

The electrode portions of the third chip component 1504 are connected to the power supply pad 1503PV1. The electrode portions of the third chip component 1504 are connected to one of the electrode portions of the second chip component 1501 piled up thereon. Further, the electrode portions of the first chip component 1503 and the fifth chip component 1506 are connected to the GND pad 1503PG1. The electrode portions of the first chip component 1503 and the fifth chip component 1506 are connected to the other electrode portion of the second chip component 1501 piled up thereon.

The electrode portions of the fifth chip component 1506 are connected to the power supply pad 1505PV1. The electrode portions of the fifth chip component 1506 are connected to one electrode portion of the second chip component 1501 piled up thereon. Further, the electrode portions of the third chip component 1504 and the fourth chip component 1505 are connected to the GND pad 1505PG1. Each electrode portion of the third chip component 1504 and the fourth chip component 1505 is connected to the other electrode portion of the sixth chip component 1502 stacked on top. With the above configuration, the number of mounted components can be increased.

### Sixteenth Embodiment

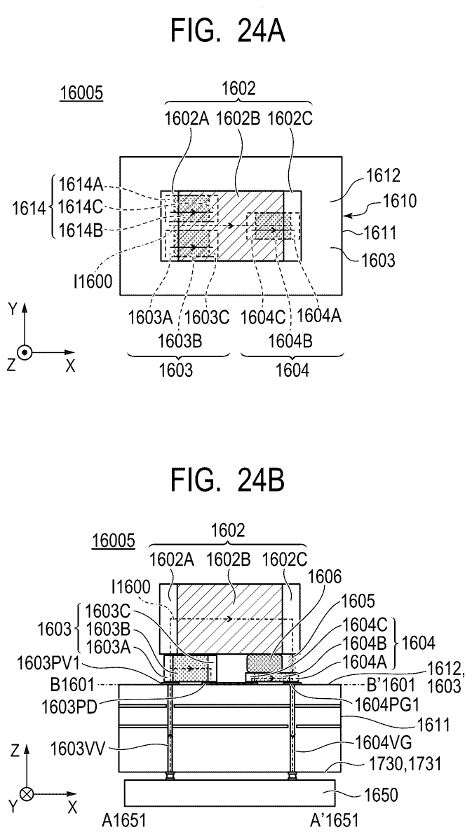

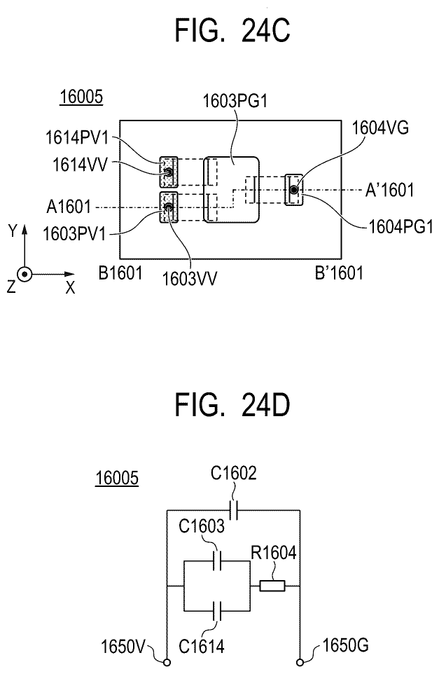

FIG. 24A is a plane view illustrating a processing module 16005 according to a sixteenth embodiment. FIG. 24B is a cross-sectional view in the XZ plane along a dotted line A1601-A′1601 of the processing module 16005. FIG. 24C is a cross-sectional view in the XY plane along a dotted line B1601-B′1601 in FIG. 24B. FIG. 24D is a diagram illustrating the processing module 16005 represented by an equivalent circuit. The differences between the sixteenth embodiment and other embodiments, particularly the fifth embodiment, will be mainly described below.

The position of the vias in the sixteenth embodiment is different from that in the fifth embodiment. In the fifth embodiment illustrated in FIGS. 11A to 11D, a GND503VG via is connected to a GND pad 503PG1. An electrode portion 503A of the first chip component 503 is connected to a GND pad 503PG1. On the other hand, in the sixteenth embodiment, a GND via 1604VG is connected to a GND pad 1604PG1. The electrode portion 1604A of a third chip component 1604 (chip resistor R1604) is connected to a GND pad 1604PG1. Although the inductance of the via increases because the distance between the power supply via and the GND via is longer than that in the fifth embodiment, the effect of suppressing the increase in impedance due to anti-resonance can be similarly obtained.

### Seventeenth Embodiment

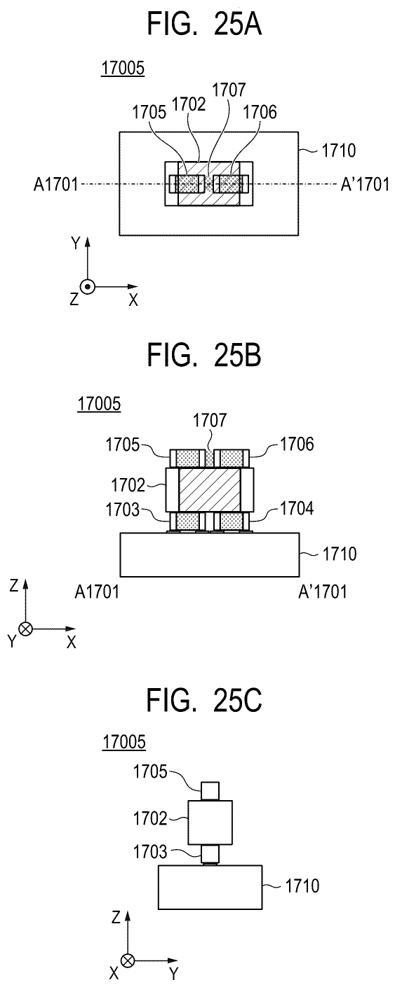

FIG. 25A is a plane view illustrating a processing module 17005 according to a seventeenth embodiment. FIG. 25B is a cross-sectional view of the XZ plane along a dotted lines A1701-A′1701 in FIG. 25A. FIG. 25C is a side view along the X-direction of the processing module 17005 according to the seventeenth embodiment. The differences between the seventeenth embodiment and the other embodiments will be mainly described below.

A first chip component 1703, a third chip component 1704, a fourth chip component 1705, and a fifth chip component 1706 are chip components of the same size, for example, a capacitor of 0402 size. The second chip component 1702 is, for example, a capacitor of 1005 size. The first chip component 1703 and the third chip component 1704 are mounted on the main surface of a printed wiring board 1710, and the fourth chip component 1705 and a fifth chip component 1706 are mounted on the first chip component 1703 and the fourth chip component and the fifth chip component 1706.

Each electrode portion of the first chip component 1703 and the third chip component 1704 is connected to a conductive pad formed on the main surface of a printed wiring board 1710. One electrode portion of the first chip component 1703 and the fourth chip component 1705 is connected to one electrode portion of the second chip component 1702, and one electrode portion of the third chip component 1704 and the fifth chip component 1706 is connected to the other electrode portion of the second chip component 1702. The electrode portion of the fourth chip component 1705 and the electrode portion of the fifth chip component 1706 are connected to each other by a conductive adhesive 1707 such as solder.

As described above, it is possible to form a plurality of circuits on a printed wiring board even in a structure in which components are stacked in three stages. According to the seventeenth embodiment, by extending the circuits in a direction perpendicular to the main surface of the printed wiring board, it is possible to reduce the occupied area of the chip components on the printed wiring board, and moreover, the flexibility of layout can be improved.

### Eighteenth Embodiment

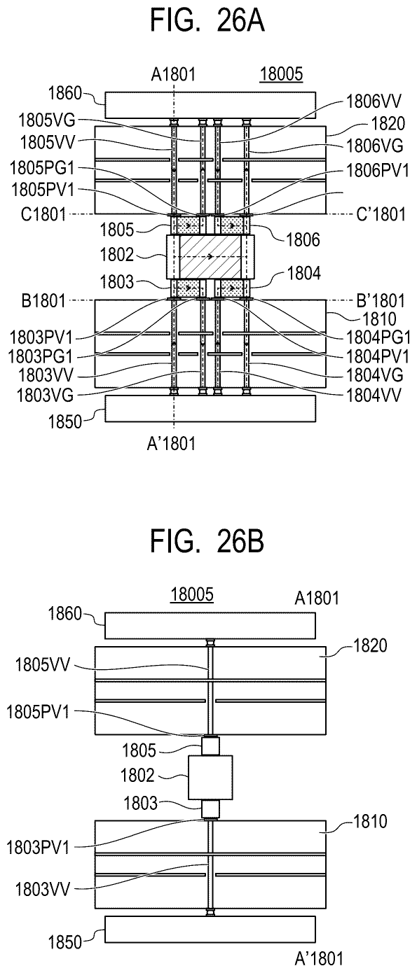

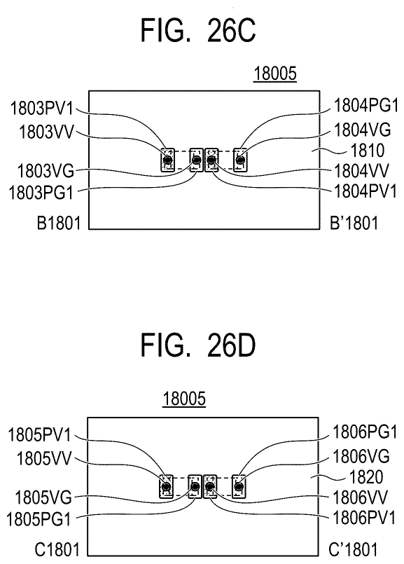

FIG. 26A is a side view illustrating a processing module 18005 according to an eighteenth embodiment. FIG. 26B is a side view of the processing module 18005 according to the eighteenth embodiment, as seen from a different direction than FIG. 26A. FIG. 26C is a cross-sectional view of the XY plane along a dotted line B1801-B′1801 in FIG. 26A. FIG. 26D is a cross-sectional view of the XY plane along a dotted line C1801-C′1801 in FIG. 26A. The differences between the eighteenth embodiment and other embodiments will be described below.

A first chip component 1803, a third chip component 1804, a fourth chip component 1805, and a fifth chip component 1806 are capacitors of the same size (first capacitor), for example, capacitors of 0402 size. A second chip component 1802 is a capacitor larger than the first capacitor (second capacitor), for example, capacitors of 1005 size. The first chip component 1803 and the third chip component 1804 are mounted on the main surface of a printed wiring board 1810. The second chip component 1802 is mounted on the first chip component 1803 and the third chip component 1804. Furthermore, the fourth chip component 1805 and the fifth chip component 1806 are mounted on the second chip component 1802. Another printed wiring board 1820 is provided on the fourth chip component 1805 and the fifth chip component 1806.

The electrode portions of the first chip component 1803 and the third chip component 1804 are connected to conductive pads formed on the main surface of the printed wiring board (first wiring board) 1810. One electrode portion of the first chip component 1803 is also connected to one electrode portion of the second chip component 1802. Similarly, one electrode portion of the third chip component 1804 is also connected to the other electrode portion of the second chip component 1802. The electrode portions of the fourth chip component 1805 and the fifth chip component 1806 are connected to a conductive pad formed on the main surface of a printed wiring board (second wiring board) 1820. One electrode portion of the fourth chip component 1805 is also connected to one electrode portion of the second chip component 1802. One electrode portion of the fifth chip component 1806 is also connected to the other electrode portion of the second chip component 1802.

Of the two main surfaces of the printed wiring board 1810, the first semiconductor device 1850 is mounted on the side where the first chip component 1803 and the third chip component 1804 are not mounted. Of the two main surfaces of the printed wiring board 1820, the second semiconductor device 1860 is mounted on the side where the fourth chip component 1805 and the fifth chip component 1806 are not mounted. As described above, a capacitor (First chip component 1803, second chip component 1802 to fifth chip component 1806) is electrically connected to the first semiconductor device 1850 and the second semiconductor device 1860 via conductor pads and vias.

With this configuration, the first semiconductor device 1850 and the second semiconductor device 1860 can share the second chip component 1802 which is a capacitor. A large-sized capacitor such as the second chip component 1802 is effective in suppressing low-frequency potential fluctuation of a semiconductor device and is more effective than a high-frequency capacitor (First chip component 1803, third chip component 1804 to fifth chip component 1806) even at a distance from the first semiconductor device 1850 and the second semiconductor device 1860. By sharing the second chip component 1802 at a position slightly apart from the first semiconductor device 1850 and the second semiconductor device 1860, the occupied area of the chip component on the main surface of the printed wiring board is reduced, and the flexibility of layout is improved.

### Nineteenth Embodiment

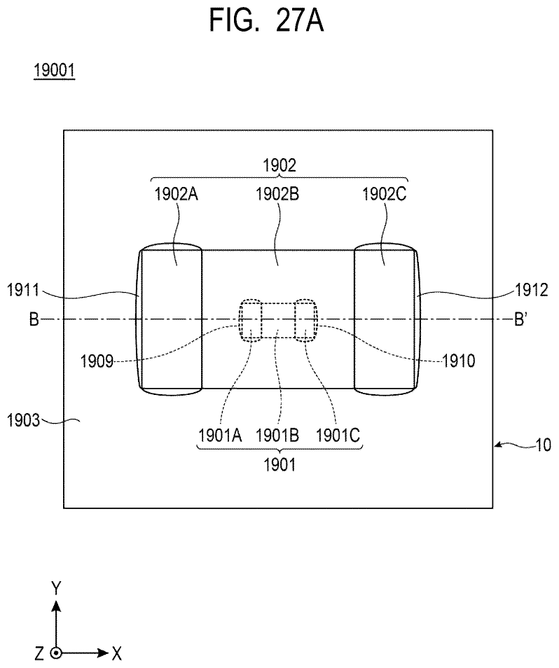

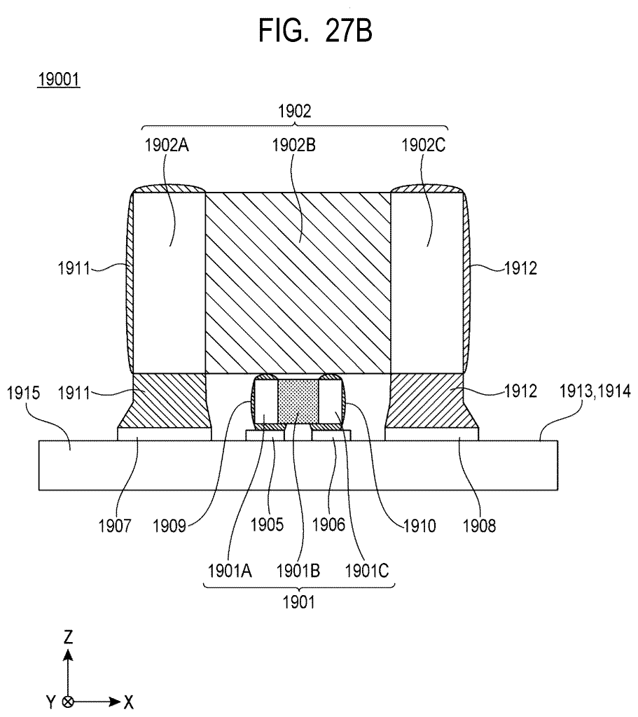

FIG. 27A is a plane view illustrating a processing module 19001 according to a nineteenth embodiment. FIG. 27B is a cross-sectional view along a dotted line B-B′ of the processing module 19001 according to the nineteenth embodiment. The printed wiring board 1903 has an insulating substrate 1915 and at least one conductor layer. The at least one conductor layer includes a surface layer 1914 located on a main surface 1913 of the insulating substrate 1915. The surface layer 1914 of the printed wiring board 1903 is provided with a first pad 1905, a second pad 1906, a third pad 1907, and a fourth pad 1908 as electrodes.

The first pad 1905 is connected to a first connecting member 1909. The second pad 1906 is connected to a second connecting member 1910. The third pad 1907 is connected to a third connecting member 1911. The fourth pad 1908 is connected to a fourth connecting member 1912. The connecting area between the third connecting member 1911 and the third pad 1907 and the connecting area between the fourth connecting member 1912 and the fourth pad 1908 are both larger than the connecting area between the first connecting member 1909 and the first pad 1905 and the connecting area between the second connecting member 1910 and the second pad 1906.

The first chip component 1901 is disposed on a surface layer 1914 of the printed wiring board 1903. The second chip component 1902 is stacked on the first chip component 1901. The first chip component 1901 and the second chip component 1902 are chip components such as capacitors, resistors, inductors, and the like.

The first chip component 1901 has a first electrode portion 1901A, a first non-electrode portion 1901B, and a second electrode portion 1901C. The second chip component 1902 has a third electrode portion 1902A, a second non-electrode portion 1902B, and a fourth electrode portion 1902C. As illustrated in FIG. 27A, the longitudinal directions of the first chip component 1901 and the second chip component 1902 are the same axial direction (X axis direction in the figure).

The first electrode portion 1901A of the first chip component 1901 is connected to the first pad 1905 provided on the printed wiring board 1903 via the first connecting member 1909. The third electrode portion 1902A of the second chip component 1902 is connected to the third pad 1907 provided on the printed wiring board 1903 via the third connecting member 1911. The first electrode portion 1901A and the third electrode portion 1902A are not connected to each other via the first connecting member 1909 and the third connecting member 1911.

The second electrode portion 1901C of the first chip component 1901 is connected to the second pad 1906 provided on the printed wiring board 1903 via the second connecting member 1910. The fourth electrode portion 1902C of the second chip component 1902 is connected to the fourth pad 1908 provided on the printed wiring board 1903 via the fourth connecting member 1912. The second electrode portion 1901C and the fourth electrode portion 1902C are not connected via the second connecting member 1910 and the fourth connecting member 1912. As described above, the first connecting member 1909, the second connecting member 1910, the third connecting member 1911, and the fourth connecting member 1912 are separated from each other.

The first connecting member 1909 electrically connects only the first electrode portion 1901A of the first chip component 1901 and the first pad 1905 of the printed wiring board 1903. The second connecting member 1910 electrically connects only the second electrode portion 1901C of the first chip component 1901 and the second pad 1906 of the printed wiring board 1903. The first connecting member 1909 and the second connecting member 1910 are in contact with the second non-electrode portion 1902B of the second chip component 1902.

The third connecting member 1911 connects only the third electrode portion 1902A of the second chip component 1902 and the third pad 1907 of the printed wiring board 1903. The fourth connecting member 1912 connects only the fourth electrode portion 1902C of the second chip component 1902 and the fourth pad 1908 of the printed wiring board 1903. That is, there is a gap between the first electrode portion 1901A and the third electrode portion 1902A. Similarly, there is a gap between the second electrode portion 1901C and the fourth electrode portion 1902C. Thereby, the first electrode portion 1901A is electrically isolated from the third electrode portion 1902A and the fourth electrode portion 1902C via a gap in the stacking direction between the first chip component 1901 and the second chip component 1902. Similarly, the second electrode portion 1901C is electrically isolated from the third electrode portion 1902A and the fourth electrode portion 1902C via a gap in the stacking direction between the first chip component 1901 and the second chip component 1902.

Thereby, compared with the case where the first electrode portion 1901A of the first chip component 1901, the third electrode portion 1902A of the second chip component 1902, and the third pad 1907 of the printed wiring board 1903 are connected by the same connecting member, the amount of connecting member to be supplied can be greatly reduced. Therefore, since the minimum required connecting member can be supplied at the time of manufacturing and the printed wiring board, the first chip component 1901, and the second chip component 1902 can be connected, it is possible to narrow the spacing between the printed wiring board 1903 and the other electronic components. In other words, chip components can be laid out on the printed wiring board 1903 at high density while minimizing constraints on the connecting member supply process, so that the printed wiring board 1903 can be miniaturized.

No other chip components are disposed between the third electrode portion 1902A of the second chip component 1902 and the third pad 1907 of the printed wiring board 1903, and between the fourth electrode portion 1902C of the second chip component 1902 and the fourth pad 1908 of the printed wiring board 1903. Therefore, the third pad 1907 and the fourth pad 1908 are provided on the surface layer 1914 of the printed wiring board 1903 with an area similar to that of the third electrode portion 1902A and the fourth electrode portion 1902C. Furthermore, the second chip component 1902 can be stacked on the first chip component 1901 without reducing the connecting area of the electrodes of the second chip component 1902. That is, since the joining strength of the second chip component 1902 can be secured without being affected by the size of the first chip component 1901, the stacked structure of chip components having high joining strength can be realized.

In FIG. 27A, the first pad 1905 and the third pad 1907 of the printed wiring board 1903 are not electrically connected by wiring. However, if the first pad 1905 and the third pad 1907 are connected by wiring, they can be electrically connected, and if the first pad 1905 and the third pad 1907 are not connected by wiring, they can be electrically isolated.

Similarly, the second pad 1906 and the fourth pad 1908 of the printed wiring board 1903 are not connected. However, if the second pad 1906 and the fourth pad 1908 are connected by wiring, they can be electrically connected, and if the second pad 1906 and the fourth pad 1908 are not connected by wiring, they can be electrically isolated. As described above, by connecting the electrode portions of the two upper and lower chip components to a plurality of pads (electrodes) provided on the printed wiring board 1903, it is possible to select whether they are electrically connected or isolated by wiring of the printed wiring board 1903. Therefore, the degree of freedom of wiring layout in the printed wiring board 1903 can be improved.

When the second chip component 1902 is larger than the first chip component 1901, for example, the size of the first chip component 1901 is 0402 size and a component of 0603 size as the second chip component 1902 is stacked on the first chip component 1901. In the case of a combination of the first chip component 1901 of 0402 size with the lower tolerance limit and the second chip component 1902 of 0603 size with the upper tolerance limit, positional deviation of the electrodes of the chip components occurs. Therefore, it is difficult to manufacture an excellent product. However, even when chip components of different sizes are stacked as in the nineteenth embodiment, by providing separate electrodes on the printed wiring board 1903 and joining them with connecting members, it is possible to manufacture with good yield even if the electrode positions do not completely overlap due to the tolerance.

As illustrated in FIG. 27B, the first electrode portion 1901A is covered with the first connecting member 1909 and is in contact with the second non-electrode portion 1902B of the second chip component 1902. There is a gap between the first non-electrode portion 1901B and the second non-electrode portion 1902B. The second electrode portion 1901C is covered with the second connecting member 1910 and is in contact with the second non-electrode portion 1902B of the second chip component 1902. As illustrated in FIG. 27A, in the plane view of the printed wiring board 1903, the center of gravity of the second chip component 1902 is included in the region where the first chip component 1901 is disposed.

As long as the third connecting member 1911 has a shape stretched from a spherical shape and joins the third electrode portion 1902A to the third pad 1907. Similarly, the fourth connecting member 1912 has a shape stretched from a spherical shape and joins the fourth electrode portion 1902C to the fourth pad 1908. Thereby, when solder is melted in the reflow furnace, the second non-electrode portion 1902B of the second chip component 1902 is pressed against the first electrode portion 1901A and the second electrode portion 1901C of the first chip component 1901 by the surface tension of the solder of the second chip component 1902, and the connection state is established. Furthermore, as illustrated in FIG. 27A, the center of gravity of the second chip component 1902 is included in the region where the first chip component 1901 is disposed. Thereby, the second chip component 1902 stacked on the first chip component 1901 can be stacked in a stable state, and the yield during manufacturing can be improved.

The first connecting member 1909, the second connecting member 1910, the third connecting member 1911, and the fourth connecting member 1912 are solder. In the nineteenth embodiment, the first connecting member 1909, the second connecting member 1910, the third connecting member 1911, and the fourth connecting member 1912 are electrically isolated from each other. By using solder as the connecting member, for example, the first connecting member 1909 and the second connecting member 1910 can be supplied with solder by screen printing. The third connecting member 1911 and the fourth connecting member 1912 can also be manufactured by combining them with solder balls or solder preforms. As described above, by using solder as a connecting member, the degree of freedom of the connecting member supply method can be improved.

In the nineteenth embodiment, the size of the second chip component 1902 is larger than the size of the first chip component 1901. For example, the first chip component 1901 is a chip component of 0402 size, and the second chip component 1902 is a chip component of 1608 size. The connecting area between the first electrode portion 1901A and the second electrode portion 1901C of the first chip component 1901 and the first pad 1905 and the second pad 1906 of the printed wiring board 1903 was calculated based on the size 0402 of general-use chip multilayer ceramic capacitors published by Murata Corporation. As a result, the connecting area was 0.1125 mm×0.2 mm=0.0225 mm². Similarly, the connecting area between the third electrode portion 1902A and the fourth electrode portion 1902C of the second chip component 1902 and the third pad 1907 and the fourth pad 1908 of the printed wiring board 1903 was calculated based on the size 1608 of general-use chip multilayer ceramic capacitor published by Murata Corporation. As a result, the connecting area was 0.35 mm×0.8 mm=0.28 mm². The occupied area of the printed wiring board 1903 by the stacked structure of the first chip component 1901 and the second chip component 1902 in the nineteenth Embodiment is 1.6 mm×0.8 mm=1.28 mm².

As described above, the third electrode portion 1902A and the fourth electrode portion 1902C of the second chip component 1902 are directly connected to the third pad 1907 and the fourth pad 1908 provided on the printed wiring board 1903 by a connecting member. Thereby, the connecting area with the printed wiring board 1903 can be secured regardless of the size of the first chip component 1901 located below the second chip component 1902. Therefore, the joining strength of the second chip component 1902 can be secured to the joining strength of the second chip component 1902 without being affected by the size of the first chip component 1901, so that the stacked structure of chip components with high joining strength can be realized.

### Twentieth Embodiment

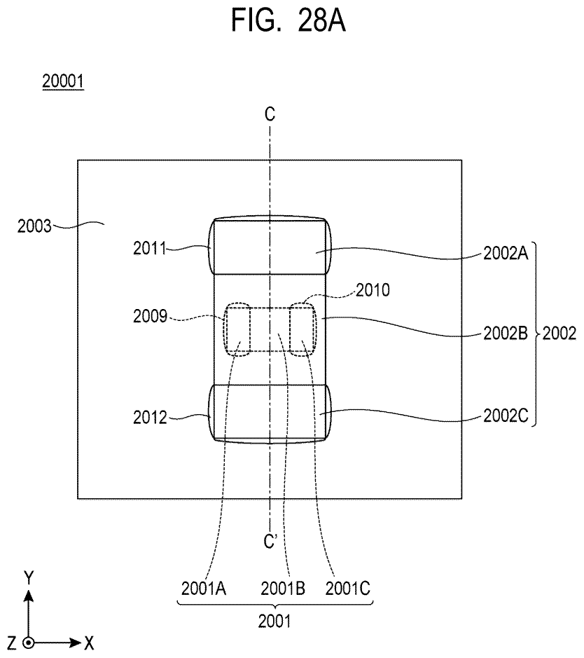

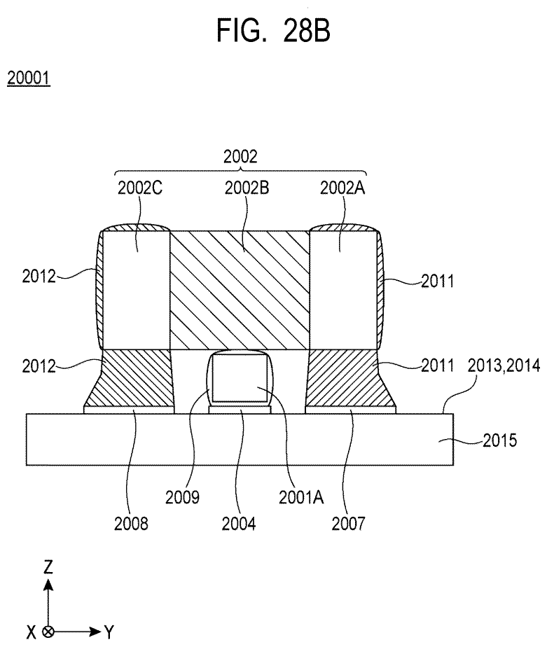

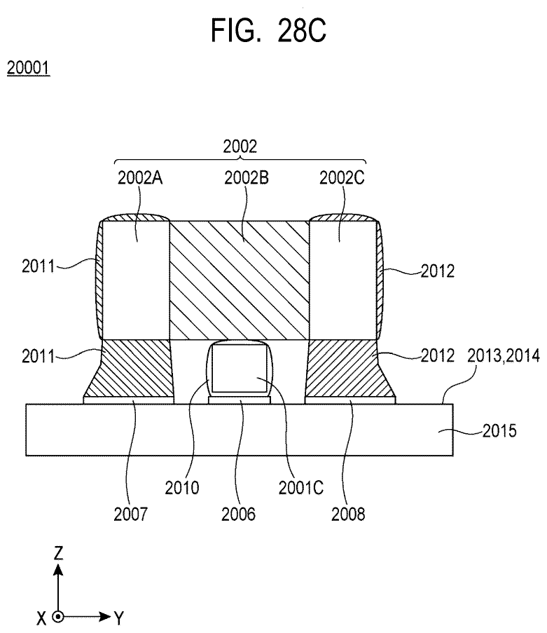

FIG. 28A is a plane view illustrating a processing module 20001 according to a twentieth embodiment. FIG. 28B and FIG. 28C are cross-sectional views along a dotted line C-C′ of the processing module 20001 according to the twentieth embodiment. FIG. 28B is a view of the cross section along the line C-C′ of FIG. 28A viewed in the negative X-direction. FIG. 28C is a view of the cross section viewed in the positive X-direction. The printed wiring board 2003 has an insulating substrate 2015 and at least one conductor layer. The at least one conductor layer includes a surface layer 2014 positioned on the main surface 2013 of the insulating substrate 2015. The surface layer 2014 of the printed wiring board 2003 is provided with a first pad 2004, a second pad 2006, a third pad 2007, and a fourth pad 2008 as electrodes.

The first chip component 2001 is disposed on the surface layer 2014 of the printed wiring board 2003. The second chip component 2002 is stacked on the first chip component 2001. The first chip component 2001 and the second chip component 2002 are chip components such as capacitors, resistors, inductors, and the like.

As illustrated in FIG. 28B, the first electrode portion 2001A of the first chip component 2001 is connected to the first pad 2004 provided on the printed wiring board 2003 via the first connecting member 2009. The third electrode portion 2002A of the second chip component 2002 is connected to the third pad 2007 provided on the printed wiring board 2003 via the third connecting member 2011. Further, the first electrode portion 2001A and the third electrode portion 2002A are not bonded via the first connecting member 2009 and the third connecting member 2011.

As illustrated in FIG. 28C, the second electrode portion 2001C of the first chip component 2001 is connected to the second pad 2006 provided on the printed wiring board 2003 via the second connecting member 2010. The fourth electrode portion 2002C of the second chip component 2002 is connected to the fourth pad 2008 provided on the printed wiring board 2003 via the fourth connecting member 2012. The second electrode portion 2001C and the fourth electrode portion 2002C are not bonded via the second connecting member 2010 and the fourth connecting member 2012.

The first connecting member 2009 connects only the first electrode portion 2001A of the first chip component 2001 and the first pad 2004 of the printed wiring board 2003. The second connecting member 2010 connects only the second electrode portion 2001C of the first chip component 2001 and the second pad 2006 of the printed wiring board 2003.

The third connecting member 2011 connects only the third electrode portion 2002A of the second chip component 2002 and the third pad 2007 of the printed wiring board 2003. The fourth connecting member 2012 connects only the fourth electrode portion 2002C of the second chip component 2002 and the fourth pad 2008 of the printed wiring board 2003. That is, there is a gap between the first electrode portion 2001A and the third electrode portion 2002A. Similarly, there is a gap between the second electrode portion 2001C and the fourth electrode portion 2002C.

The differences between the twentieth embodiment and the nineteenth embodiment will be explained below. In the twentieth embodiment, the second chip component 2002 is stacked on the first chip component 2001 in a state where the longitudinal direction of the first chip component 2001 and the longitudinal direction of the second chip component 2002 are orthogonal. The first chip component 2001 has a first electrode portion 2001A, a first non-electrode portion 2001B, and a second electrode portion 2001C. The second chip component 2002 has a third electrode portion 2002A, a second non-electrode portion 2002B, and a fourth electrode portion 2002C.

Although FIG. 28A shows a state where the longitudinal directions of the first chip component 2001 and the second chip component 2002 are orthogonal, they do not necessarily have to be orthogonal. To the extent that the first chip component 2001 contacts the second non-electrode portion 2002B of the second chip component 2002 and a gap is provided between the electrode portion of the first chip component 2001 and the electrode portion of the second chip component 2002, the longitudinal axes of the first chip component and the second chip component may intersect at an angle other than 90 degrees.

In the twentieth embodiment, the size of the second chip component 2002 is larger than the size of the first chip component 2001. For example, the first chip component 2001 is a chip component of 0402 size, and the second chip component 2002 is a chip component of 1005 size. According to the external tolerances of general-use chip multilayer ceramic capacitors published by Murata Corporation, the external dimensions of the 0402 size are 0.45 mm×0.25 mm at the maximum, and the size of the non-electrode portion of 1005 size is 0.45 mm×0.3 mm at the minimum. Therefore, even in consideration of the external tolerances of the chip components, by making the longitudinal directions of the first chip component and the second chip component orthogonal, the 0402 size of the first chip component 2001 can be disposed within the range of the 1005 size of the non-electrode portion of the second chip component 2002. That is, since the first electrode portion 200A of the first chip component 2001, the third electrode portion 2002A of the second chip component 2002, the second electrode portion 2001C of the first chip component 2001 and the fourth electrode portion 2002C of the second chip component 2002 and the first pad 2004, the second pad 2006, the third pad 2007, and the fourth pad 2008 of the printed wiring board 2003 and the third electrode portion 2002A and the fourth electrode portion 2002C of the second chip component 2002 can be isolated, the short circuit risk can be reduced.

In the twentieth embodiment, the occupied area of the printed wiring board 2003 by the stacked structure of the first chip component 2001 and the second chip component 2002 is 1.0 mm×0.5 mm=0.50 mm². As described above, unlike the nineteenth embodiment, the second chip component 2002 can be stacked with 1005-sized components instead of 1608-sized components. Therefore, in the twentieth embodiment, chip components can be disposed at a higher density than in the nineteenth embodiment.

### Modified Embodiment

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

The configurations described as printed circuit boards and printed wiring boards are manufactured by various printing technologies (printing technologies) such as screen printing, flexographic printing, gravure printing, inkjet printing, and offset printing. However, the use of printing technologies (printing technologies) is not required, and photolithography technologies and film formation/etching technologies such as semiconductor manufacturing technologies can also be used. In addition to printed circuit boards and printed wiring boards, those that do not use printing technologies can also be called circuit boards and wiring boards. For example, a silicon interposer is an example of a wiring board manufactured using semiconductor manufacturing technologies.

An electronic device in which a circuit board is disposed in the housing of an electronic device is not limited to a camera. For example, the electronic device may be a mobile communication device. For example, the electronic device may be an information device such as a smartphone or a personal computer, or a communication device such as a modem or a router. Alternatively, the electronic equipment may be office equipment such as printers and copiers, medical equipment such as radiography equipment, magnetic imaging equipment, ultrasonic imaging equipment, and endoscopes, industrial equipment such as robots and semiconductor manufacturing equipment, and transportation equipment such as vehicles, airplanes, and ships. In a limited space in the housing of the electronic device, the electronic device can be miniaturized and densified by using the electronic module of the present disclosure. In an electronic device having a plurality of electronic modules, the electronic device can be miniaturized and densified by using the circuit board of the present disclosure.

The disclosure of the present specification includes not only what is explicitly described in the present specification but also all matters that can be understood from the present specification and the drawings attached thereto. The disclosure of the present specification also includes a complement of the individual concepts described herein. That is, if, for example, “A is B” is stated in this specification, it can be said that “A is not B” is disclosed even if the statement “A is not B” is omitted. This is because when “A is B” is stated, it is assumed that the case “A is not B” is considered.

This application claims the benefit of Japanese Patent Application No. 2024-050038, filed Mar. 26, 2024, and Japanese Patent Application No. 2024-185243, filed Oct. 21, 2024, which are hereby incorporated by reference herein in their entirety.

What is claimed is:

1. A module comprising:
a wiring board;
a first chip component that has a first electrode portion, a first non-electrode portion, and a second electrode portion and is provided on the wiring board; and
a second chip component that has a third electrode portion, a second non-electrode portion, and a fourth electrode portion and is stacked on the first chip component;
wherein the second electrode portion is electrically isolated from the third electrode portion and the fourth electrode portion, and
wherein the second electrode portion is located between the second non-electrode portion and the wiring board.

2. A module comprising:
a wiring board;
a first chip component that has a first electrode portion, a first non-electrode portion, and a second electrode portion and is provided on the wiring board; and
a second chip component that has a third electrode portion, a second non-electrode portion, and a fourth electrode portion and is stacked on the first chip component;
wherein the third electrode portion is electrically isolated from the first electrode portion and the second electrode portion, and
wherein the first non-electrode portion is located between the third electrode portion and the wiring board.

3. A module comprising:
a wiring board;
a first chip component that has a first electrode portion, a first non-electrode portion, and a second electrode portion and is provided on the wiring board; and
a second chip component that has a third electrode portion, a second non-electrode portion, and a fourth electrode portion and is stacked on the first chip component,
wherein the first electrode portion is connected to the wiring board via a first connecting member,
wherein the second electrode portion is connected to the wiring board via a second connecting member,
wherein the third electrode portion is connected to the wiring board via a third connecting member,
wherein the fourth electrode portion is connected to the wiring board via a fourth connecting member, and
wherein the first connecting member, the second connecting member, the third connecting member, and the fourth connecting member are separated from each other.

4. The module according to claim 1, wherein the second electrode portion is electrically isolated from the third electrode portion and the fourth electrode portion via a gap in the stacking direction between the first chip component and the second chip component.

5. The module according to claim 2, wherein the third electrode portion is electrically isolated from the first electrode portion and the second electrode portion via a gap in the stacking direction of the first chip portion and the second chip portion.

6. The module according to claim 2, wherein the size of the second chip portion is larger than the size of the first chip portion.

7. The module according to claim 5, wherein the distance of the gap is less than 200 μm.

8. The module according to claim 4, further comprising:
a third chip portion that has a fifth electrode portion, a third non-electrode portion, and a sixth electrode portion and is provided on the wiring board,
wherein the third chip portion is disposed between the wiring board and the second chip portion.

9. The module according to claim 8,
wherein the sixth electrode portion is electrically isolated from the third electrode portion and the fourth electrode portion via the gap and is located between the second non-electrode portion and the wiring board, and/or
wherein the fourth electrode portion is electrically isolated from the fifth electrode portion and the sixth electrode portion via the gap, and the third non-electrode portion is located between the fourth electrode portion and the wiring board.

10. The module according to claim 3, wherein, in a plane view of the wiring board, the center of gravity of the second chip component is included within a region where the first chip component is disposed.

11. The module according to claim 8, wherein the size of the second chip component is larger than the sizes of the first chip component and the third chip component.

12. The module according to claim 2, wherein the first electrode portion is electrically connected to the third electrode portion or the fourth electrode portion.

13. The module according to claim 8, wherein the fifth electrode portion is electrically connected to the third electrode portion or the fourth electrode portion.

14. The module according to claim 8, further comprising:
a fourth chip component that has a seventh electrode portion, a fourth non-electrode portion, and an eighth electrode portion, and is provided on the wiring board between the first chip component and the third chip component,
wherein the size of the second chip component is larger than the sizes of the first chip component, the third chip component, and the fourth chip component;
wherein the seventh electrode portion and the eighth electrode portion are electrically isolated from the third electrode portion and the fourth electrode portion via the gap; and
wherein the seventh electrode portion and the eighth electrode portion are located between the second non-electrode portion and the wiring board.

15. The module according to claim 14,
wherein each of the second electrode portion, the sixth electrode portion, the seventh electrode portion, and the eighth electrode portion partially protrudes from the second non-electrode portion in a top view, and/or
wherein the third electrode portion and the fourth electrode portion partially protrudes from the first non-electrode portion, the third non-electrode portion, and the fourth non-electrode portion in a plane view.

16. The module according to claim 3, wherein the first connecting member and the second connecting member are in contact with the second non-electrode portion and/or wherein the first electrode portion is in contact with the second non-electrode portion.

17. The module according to claim 14, wherein the length of each long side of the first chip component, the third chip component, and the fourth chip component is less than half of the length of the long side of the second chip component.

18. The module according to claim 14,
wherein the first chip component, the third chip component, and the fourth chip component are disposed linearly along the longitudinal direction of the second chip component, and/or,
wherein the first chip component, the third chip component, and the fourth chip component are disposed more in the longitudinal direction than in the short-side direction of the second chip component.

19. The module according to claim 3, wherein the wiring board includes:
a first pad connected to the first connecting member;
a second pad connected to the second connecting member;
a third pad connected to the third connecting member; and
a fourth pad connected to the fourth connecting member,
wherein each of a connecting area between the third connecting member and the third pad, and a connecting area between the fourth connecting member and the fourth pad, is larger than a connecting area between the first connecting member and the first pad, and a connecting area between the second connecting member and the second pad.

20. The module according to claim 14, further comprising:
a plurality of power supply vias and a plurality of GND vias that are disposed at positions overlapping any of the first electrode portion, the second electrode portion, the fifth electrode portion, the sixth electrode portion, the seventh electrode portion, and the eighth electrode portion in a plane view.

21. The module according to claim 14, further comprising:
a semiconductor device that includes a power supply terminal and a GND terminal and is provided on the wiring board,
wherein the plurality of power supply vias connect the power supply terminal to each of the first electrode portion, the fifth electrode portion, and the seventh electrode portion,
wherein the plurality of GND vias connect the GND terminal to each of the second electrode portion, the sixth electrode portion, and the eighth electrode portion, and
wherein the plurality of power supply vias and the plurality of GND vias are disposed parallel to each other in cross-sectional view.

22. The module according to claim 21, wherein the first chip component, the third chip component, and the fourth chip component are first capacitors of the same size, and
wherein the second chip component is a second capacitor larger than the first capacitor.

23. The module according to claim 21,
wherein the plurality of power supply vias and the plurality of GND vias are respectively connected to the first chip component, the third chip component, and the fourth chip component such that directions of currents in the first chip component, the third chip component, and the fourth chip component are opposed between components adjacent to each other in a plane view, and/or
wherein directions of currents are opposed between vias adjacent to each other among the plurality of power supply vias and the plurality of GND vias.

24. The module according to claim 21, wherein at least one of the first chip component, the second chip component, the third chip component, and the fourth chip component is a chip resistor.

25. The module according to claim 22,
wherein the second capacitor and the chip resistor are connected in series to the power terminal and the GND terminal, and the first capacitor is connected to the power terminal and the GND terminal, and/or
wherein the first capacitor and the chip resistor are connected in series to the power supply terminal and the GND terminal, and the second capacitor is connected to the power terminal and the GND terminal.

26. The module according to claim 3, wherein the first connecting member, the second connecting member, the third connecting member, and the fourth connecting member are solder, and
wherein the first connecting member, the second connecting member, the third connecting member, and the fourth connecting member are electrically isolated.

27. The module according to claim 21, wherein the wiring board is set as a first wiring board, and the semiconductor device is set as a first semiconductor device,
wherein the module further comprising:
a second wiring board; and
a second semiconductor device provided on the second wiring board,
wherein the first chip component, the second chip component, the third chip component, and the fourth chip component are disposed between the first wiring board and the second wiring board, and
wherein the first semiconductor device is electrically connected to the second semiconductor device via the first chip component, the second chip component, the third chip component, and the fourth chip component.

28. An apparatus comprising:
a housing; and
the module according to claim 1, which is disposed in the housing.

29. An apparatus comprising:
a first module including the module according to claim 2; and
a second module,
wherein the first module is electrically connected to the second module via a connecting member.

30. An apparatus having a plurality of electronic modules,
wherein at least one among the plurality of electronic modules is the module according to claim 3,
wherein the apparatus is any one of a camera, a communication apparatus, an information apparatus, an office apparatus, an office apparatus, an industrial apparatus, and a transportation apparatus.
